(19) United States
(12) Patent Application Publication
(10) Pub. No.: US 2025/0255126 A1
(43) Pub. Date: Aug. 7, 2025

(54) DISPLAY DEVICE

(71) Applicant: LG Display Co., Ltd., Seoul (KR)

(72) Inventors: MyungHo Ban, Paju-si (KR); KyungMin Kim, Paju-si (KR); Hyemin Park, Paju-si (KR)

(73) Assignee: LG Display Co., Ltd., Seoul (KR)

(21) Appl. No.: 19/002,467

(22) Filed: Dec. 26, 2024

(30) Foreign Application Priority Data
Feb. 2, 2024 (KR) 10-2024-0016855

(51) Int. Cl. H10K 59/131; G09G 3/3258; H10K 59/80

(52) U.S. Cl. CPC H10K 59/131; G09G 3/3258; H10K 59/80521; H10K 59/878

(57) ABSTRACT

A display device according to an example of the present disclosure can include a substrate, a first protective layer on the substrate, a lower insulating layer on the first protective layer, a first upper insulating layer on the lower insulating layer, a second upper insulating layer on the lower insulating layer and spaced apart from the first upper insulating layer in a first direction, a first pixel electrode on the first upper insulating layer, a second pixel electrode on the lower insulating layer and disposed between one side of the first upper insulating layer and another side of the second upper insulating layer, and a third pixel electrode on the second upper insulating layer.

### CROSS REFERENCE TO RELATED APPLICATION

This application claims priority to Korean Patent Application No. 10-2024-0016855, filed in the Republic of Korea on Feb. 2, 2024, the entire contents of which is hereby expressly incorporated by reference into the present application.

### BACKGROUND

### Field

Embodiments of the present disclosure relate to a display device.

### Discussion of the Related Art

Among display devices, there is a self-luminous display device in which a display panel emits light on its own. In the case of a self-luminous display device, the display panel can include a light emitting device for each subpixel.

Meanwhile, the light generated from the light emitting devices of the display panel can pass through various components within the display panel, and come out of the display panel.

The description provided in the background section should not be assumed to be prior art merely because it is mentioned in or associated with the background section. The background section may include information that describes one or more aspects of the subject technology.

### SUMMARY OF THE DISCLOSURE

However, among the light generated from the light emitting device, there can be light that does not come out of the display panel and is trapped inside the display panel.

Among the light generated from the light emitting device, the more light that does not come out of the display panel and is trapped inside the display panel, the lower the luminance of the corresponding subpixel can be. Accordingly, as a result, the quality of the image displayed on the display panel can be deteriorated.

Embodiments of the present disclosure can provide a display device having a light extraction structure which allows a greater amount of light among the light generated by the light emitting devices in the display panel to be emitted toward a viewing surface.

Embodiments of the present disclosure can provide a display device having a light extraction structure suitable for a high-resolution display panel.

Embodiments of the present disclosure can provide a display device with a compensation function capable of reducing luminance deviation for each subpixel according to a light extraction structure suitable for high-resolution display panels.

A display device according to embodiments of the present disclosure can include a substrate, a first protective layer on the substrate, a lower insulating layer on the first protective layer, a first upper insulating layer on the lower insulating layer, a second upper insulating layer on the lower insulating layer and spaced apart from the first upper insulating layer in a first direction, a first pixel electrode on the first upper insulating layer, a second pixel electrode on the lower insulating layer and disposed between one side of the first upper insulating layer and another side of the second upper insulating layer, and a third pixel electrode on the second upper insulating layer.

The display device according to embodiments of the present disclosure can further include a fourth pixel electrode on the lower insulating layer and disposed on one side of the second upper insulating layer, a third upper insulating layer on the lower insulating layer and disposed on one side of the second pixel electrode in a second direction different from the first direction, and a fifth pixel electrode on the third upper insulating layer. The first pixel electrode, the second pixel electrode, the third pixel electrode, the fourth pixel electrode, and the fifth pixel electrode can be included in a first subpixel, a second subpixel, a third subpixel, a fourth subpixel, and a fifth subpixel, respectively.

In the display device according to embodiments of the present disclosure, the second pixel electrode and the fourth pixel electrode can be located closer to the substrate than the first pixel electrode, the third pixel electrode, and the fifth pixel electrode.

The display device according to embodiments of the present disclosure can further include an intermediate layer located on the first pixel electrode, the second pixel electrode, the third pixel electrode, the fourth pixel electrode, and the fifth pixel electrode, and a common electrode located on the intermediate layer and including a reflective electrode material.

In the display device according to embodiments of the present disclosure, the common electrode can include a plurality of inclined surfaces.

In the display device according to embodiments of the present disclosure, the common electrode can have an inclined surface on each side of the first upper insulating layer, the second upper insulating layer, and the third upper insulating layer, and can have an inclined surface on a side of the lower insulating layer.

In the display device according to embodiments of the present disclosure, the common electrode can have an inclined surface on each of four sides of each of the first upper insulating layer, the second upper insulating layer, and the third upper insulating layer, and can have an inclined surface on each of two sides among four sides of the lower insulating layer.

A display device according to embodiments of the present disclosure can include a substrate, a first pixel electrode, a second pixel electrode, and a third pixel electrode on the substrate, an intermediate layer on the first pixel electrode, the second pixel electrode, and the third pixel electrode, and a common electrode on the intermediate layer. The first pixel electrode and the third pixel electrode can be located higher from the substrate than the second pixel electrode.

In the display device according to embodiments of the present disclosure, the common electrode can include an inclined surface extending from an upper portion of the first pixel electrode, passing through one side of the first pixel electrode, and extending to an upper portion of the second pixel electrode, and an inclined surface extending from an upper portion of the third pixel electrode, passing through the other side of the third pixel electrode, and extending to an upper portion of the second pixel electrode.

The display device according to embodiments of the present disclosure can further include an insulating layer which is not disposed below the second pixel electrode, but is disposed in an island shape below each of the first pixel electrode and the third pixel electrode.

A display device according to embodiments of the present disclosure can include a substrate, a first subpixel including a first light emitting device, a second subpixel adjacent to the first subpixel in a first direction and including a second light emitting device, a first data line supplying a first data voltage to the first subpixel, and a second data line supplying a second data voltage to the second subpixel.

In the display device according to embodiments of the present disclosure, the first light emitting device can be located at a first height from the substrate, and the second light emitting device can be located at a second height lower than the first height from the substrate.

In the display device according to embodiments of the present disclosure, if an emission luminance of the first subpixel, an emission luminance of the second subpixel, and an emission luminance of the third subpixel are the same, the second data voltage can be higher than the first data voltage.

The display device according to embodiments of the present disclosure can further include a first protective layer on the substrate, a lower insulating layer on the first protective layer, a first upper insulating layer located on the lower insulating layer, a first pixel electrode located on the first upper insulating layer, a second pixel electrode located on the lower insulating layer and disposed on one side of the first upper insulating layer, an intermediate layer on the first pixel electrode and the second pixel electrode, and a common electrode on the intermediate layer.

In the display device according to embodiments of the present disclosure, the first light emitting device can include the first pixel electrode, the intermediate layer, and the common electrode, and the second light emitting device can include the second pixel electrode, the intermediate layer, and the common electrode.

In the display device according to embodiments of the present disclosure, the common electrode can include four inclined surfaces located on four sides of the first upper insulating layer, and two inclined surfaces located on two of the four sides of the lower insulating layer.

According to embodiments of the present disclosure, there can provide a display device having a light extraction structure which allows a greater amount of light among the light generated by the light emitting devices in the display panel to be emitted toward a viewing surface.

According to embodiments of the present disclosure, there can provide a display device having a light extraction structure suitable for a high-resolution display panel.

According to embodiments of the present disclosure, there can provide a display device with a compensation function capable of reducing luminance deviation for each subpixel according to a light extraction structure suitable for high-resolution display panels.

According to embodiments of the present disclosure, it is possible to increase the light extraction efficiency for light generated from light emitting devices in the display panel. Accordingly, it is possible to reduce the power consumption of the display device by increasing light extraction efficiency.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a system configuration diagram of a display device according to embodiments of the present disclosure.

FIG. 2 illustrates a display panel according to embodiments of the present disclosure.

FIG. 3 illustrates subpixels of a display panel according to embodiments of the present disclosure.

FIG. 4 is a plan view of a display panel according to embodiments of the present disclosure.

FIG. 5 illustrates an area of a subpixel of a display panel according to embodiments of the present disclosure.

FIGS. 6 and 7 illustrate a light extraction structure of a display panel according to embodiments of the present disclosure.

FIG. 8 is a plan view illustrating a light extraction structure of a display panel according to embodiments of the present disclosure.

FIGS. 9 to 12 are cross-sectional views illustrating a light extraction structure of a display panel according to embodiments of the present disclosure.

FIG. 13 illustrates the number of mirrors per subpixel of the display panel according to embodiments of the present disclosure.

FIG. 14 illustrates light extraction efficiency for each subpixel of a display panel according to embodiments of the present disclosure.

FIG. 15 illustrates the light emission state for each subpixel of the display panel according to embodiments of the present disclosure.

FIG. 16 illustrates a data compensation circuit considering the light extraction structure of a display device according to embodiments of the present disclosure.

FIG. 17 illustrates data compensation values for each subpixel considering a light extraction structure of the display panel according to embodiments of the present disclosure.

FIG. 18 illustrates the light emission state of each subpixel after data compensation considering a light extraction structure of the display panel according to embodiments of the present disclosure.

### DETAILED DESCRIPTION OF THE EMBODIMENTS

Hereinafter, embodiments of the disclosure are described in detail with reference to the accompanying drawings. In assigning reference numerals to components of each drawing, the same components can be assigned the same numerals even when they are shown on different drawings. When determined to make the subject matter of the disclosure unclear, the detailed of the known art or functions can be skipped. As used herein, when a component “includes,” “has,” or “is composed of” another component, the component can add other components unless the component “only” includes, has, or is composed of” the other component. As used herein, the singular forms “a”, “an” and “the” are intended to include the plural forms as well, unless the context clearly indicates otherwise.

Such denotations as “first,” “second,” “A,” “B,” “(a),” and “(b),” can be used in describing the components of the disclosure. These denotations are provided merely to distinguish a component from another, and the essence, sequence, order, or number of the components are not limited by the denotations.

In describing the positional relationship between components, when two or more components are described as “connected”, “coupled” or “linked”, the two or more components can be directly “connected”, “coupled” or “linked,” or another component can intervene. Here, the other component can be included in one or more of the two or more components that are “connected”, “coupled” or “linked” to each other.

When such terms as, e.g., “after”, “next to”, “after”, and “before”, are used to describe the temporal flow relationship related to components, operation methods, and fabricating methods, it can include a non-continuous relationship unless the term “immediately” or “directly” is used.

When a component is designated with a value or its corresponding information (e.g., level), the value or the corresponding information can be interpreted as including a tolerance that can arise due to various factors (e.g., process factors, internal or external impacts, or noise). Further, the term “can” fully encompasses all the meanings and coverages of the term “may.”

Hereinafter, various embodiments of the disclosure are described in detail with reference to the accompanying drawings. All the components of each display device according to all embodiments of the present disclosure are operatively coupled and configured.

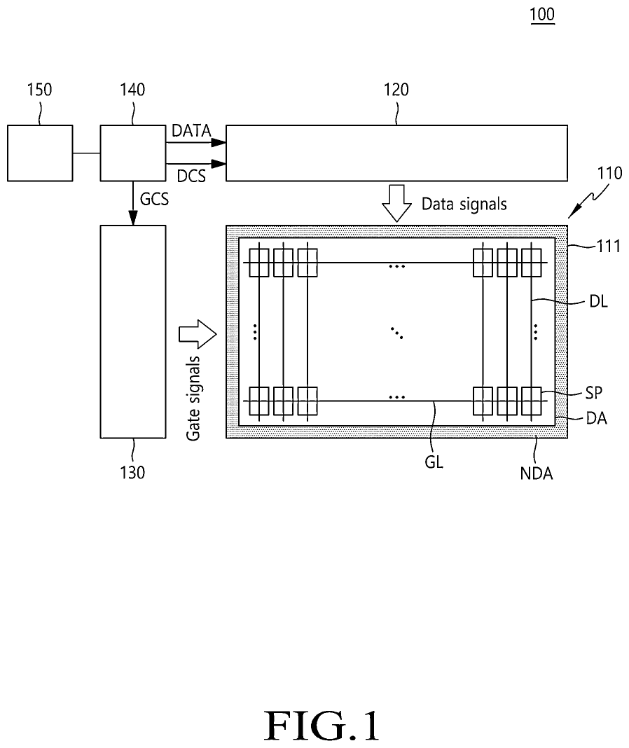

FIG. 1 is a system configuration diagram of a display device 100 according to embodiments of the present disclosure.

Referring to FIG. 1, the display device 100 according to embodiments of the present disclosure can include a display panel 110 and a display driving circuit as components for displaying an image. The display driving circuit is a circuit for driving the display panel 110, and can include a data driving circuit 120, a gate driving circuit 130, and a controller 140.

The display panel 110 can include a substrate 111 and a plurality of subpixels SP disposed on the substrate 111.

The substrate 111 of the display panel 110 can include a display area DA capable of displaying an image and a non-display area NDA located outside the display area DA. The non-display area NDA can surround the display area DA entirely or only in part(s).

The display area DA can also be referred to as an active area, and a plurality of subpixels SP for image display can be disposed in the display area DA. The non-display area NDA can also be referred to as a non-active area and can include a pad area.

In a display panel 110 according to embodiments of the present disclosure, the non-display area NDA can be very small. In this specification, the non-display area NDA can be also referred to as a “bezel.” For example, the non-display area NDA can include a first non-display area located outside the display area DA in a first direction, a second non-display area located outside the display area DA in a second direction different from the first direction, a third non-display area located outside the display area DA in the opposite direction to the first direction, and a fourth non-display area located outside the display area DA in the direction opposite to the second direction.

The first non-display area can include a pad area to which the driving circuit is connected or bonded. The second to fourth non-display areas can have a very small size.

For another example, a boundary area between the display area DA and the non-display area NDA can be bent so that the non-display area NDA can be located below the display area. In this case, when the user looks at the display device 100 from the front, there can be little or no non-display area NDA visible to the user. For example, the first non-display area can include a bending area. As the bending area is bent, the first non-display area may not be visible from the front.

Various types of signal lines for driving a plurality of subpixels SP can be disposed on the substrate 111 of the display panel 110.

The display device 100 according to embodiments of the present disclosure can be a self-luminous display device in which the display panel 110 emits light on its own. if the display device 100 according to embodiments of the present disclosure is a self-luminous display device, each of the plurality of subpixels SP can include a light emitting device.

For example, the display device 100 according to embodiments of the present disclosure can be an organic light emitting display device in which a light emitting device is implemented as an organic light emitting diode (OLED). For another example, the display device 100 according to embodiments of the present disclosure can be an inorganic light emitting display device in which the light emitting device is implemented as an inorganic-based light emitting diode. For another example, the display device 100 according to embodiments of the present disclosure can be a quantum dot display device in which a light emitting device is implemented with quantum dots, which are semiconductor crystals emitting light by itself.

The structure of each of the plurality of subpixels SP can vary depending on the type of the display device 100. For example, if the display device 100 is a self-luminous display device with the subpixel SP emitting light by itself, each subpixel SP can include a self-luminous light emitting device, one or more transistors, and one or more capacitors.

For example, various types of signal lines can include a plurality of data lines DL supplying data signals (also referred to as data voltages or image signals) and a plurality of gate lines GL for transmitting gate signals (also referred to as scan signals).

For example, the plurality of data lines DL and the plurality of gate lines GL can cross each other. Each of the plurality of data lines DL can be arranged to extend in a first direction. Each of the plurality of gate lines GL can be arranged to extend in a second direction. Here, the first direction can be a column direction and the second direction can be a row direction. Alternatively, the first direction can be a row direction and the second direction can be a column direction. Hereinafter, for convenience of explanation, it will exemplified a case in which each of the plurality of data lines DL is arranged in a column direction, and each of the plurality of gate lines GL is arranged in a row direction, however is not limited thereto.

The data driving circuit 120 is a circuit for driving a plurality of data lines DL, and can output data signals to the plurality of data lines DL.

The data driving circuit 120 can receive image data in digital form from the display controller 140 and convert the received image data into analog data signals to output to a plurality of data ines DL.

For example, the data driving circuita 120 can be connected to the display panel 110 using a tape automated bonding (TAB) method, or can be connected to the bonding pad of the display panel 110 using a chip-on-glass (COG) or chip-on-panel (COP) method, or can be implemented using a chip-on-film (COF) method and connected to the display panel 110, however is not limited thereto.

The data driving circuit 120 can be connected to one side (e.g., the upper or lower side) of the display panel 110. Depending on the driving method, panel design method, etc., the data driving circuit 120 can be connected to both sides (e.g., upper and lower sides) of the display panel 110, or can be connected to two or more of the four sides of the display panel 110.

The data driving circuit 120 can be connected to the outside of the display area DA of the display panel 110, but alternatively, it can be disposed in the display area DA of the display panel 110.

The gate driving circuit 130 is a circuit for driving a plurality of gate lines GL, and can output gate signals to the plurality of gate lines GL.

The gate driving circuit 130 can receive a first gate voltage corresponding to the turn-on level voltage and a second gate voltage corresponding to the turn-off level voltage along with various gate driving control signals GCS, and can generate gate signals and supply the generated gate signals to the plurality of gate lines GL.

In the display device 100 according to embodiments of the present disclosure, the gate driving circuit 130 can be built into the display panel 110 as a gate-in-panel (GIP) type. If the gate driving circuit 130 is a gate-in-panel type, the gate driving circuit 130 can be formed on a substrate of the display panel 110 during the manufacturing process of the display panel 110.

For example, in the display device 100 according to embodiments of the present disclosure, the gate driving circuit 130 can be disposed in the non-display area NDA of the display panel 110.

As another example, the gate driving circuit 130 can be disposed in the display area DA of the display panel 110. In this case, the gate driving circuit 130 can be disposed in a first partial area within the display area DA (e.g., a left area or a right area within the display area DA). For another example, the gate driving circuit 130 can be disposed in a first partial area within the display area DA (e.g., a left area or a right area within the display area DA) and a second partial area (e.g., a right area or a left area within the display area DA).

In the present disclosure, a gate driving circuit 130 built into the display panel 110 as a gate-in-panel type can be referred to as a “gate-in-panel circuit.”

The controller 140 can be a device for controlling the data driving circuit 120 and the gate driving circuit 130, and can control the driving timing for the plurality of data lines DL and the driving timing of the plurality of gate lines GL.

The controller 140 can supply a data driving control signal DCS to the data driving circuit 120 to control the data driving circuit 120, and can supply a gate driving control signal GCS to the gate driving circuit 130 to control the gate driving circuit 130.

The controller 140 can receive input image data from a host system 150 and supply image data DATA to the data driving circuit 120 based on the input image data.

The controller 140 can be implemented as a separate component from the data driving circuit 120, or can be integrated with the data driving circuit 120 and implemented as an integrated circuit.

The controller 140 can be a timing controller used in typical display technology, or can be a control device capable of further performing other control functions including a timing controller, or can be a control device different from the timing controller, or can be a control device other than a timing controller, or can be a circuit within the control device. The controller 140 can be implemented with various circuits or electronic components, such as an integrated circuit (IC), a field programmable gate array (FPGA), an application specific integrated circuit (ASIC), or Processor.

The controller 140 can be mounted on a printed circuit board, a flexible printed circuit, etc., and can be electrically connected to the data driving circuit 120 and the gate driving circuit 130 through a printed circuit board, a flexible printed circuit.

The controller 140 can transmit and receive signals with the data driving circuit 120 according to one or more predetermined interfaces. For example, the interface can include a low voltage differential signaling (LVDS) interface, an embedded clock point-point interface (EPI) interface, or a serial peripheral interface (SPI), however is not limited thereto.

In order to provide not only an image display function but also a touch sensing function, the display device 100 according to embodiments of the present disclosure can include a touch sensor and a touch sensing circuit for detecting an occurrenace of a touch by a touch object such as a finger or pen or detection a touch position by sensing the touch sensor.

The touch sensing circuit can include a touch driving circuit for driving and sensing a touch sensor to generate and output touch sensing data, and a touch controller for detecting the occurrence of a touch or detecting the touch position using touch sensing data.

A touch sensor can include a plurality of touch electrodes. The touch sensor can further include a plurality of touch lines to electrically connect a plurality of touch electrodes and the touch driving circuit.

The touch sensor can exist outside the display panel 110 in the form of a touch panel or can exist inside the display panel 110. If the touch sensor exists outside the display panel 110 in the form of a touch panel, the touch sensor can be referred to as an external type. If the touch sensor is an external type, the touch panel and the display panel 110 can be manufactured separately and combined during the assembly process. The external touch panel can include a touch panel substrate and a plurality of touch electrodes on the touch panel substrate.

If the touch sensor exists inside the display panel 110, the touch sensor can be formed on the substrate along with signal lines and electrodes related to display driving during the manufacturing process of the display panel 110.

The touch driving circuit can supply a touch driving signal to at least one of the plurality of touch electrodes and generate touch sensing data by sensing at least one of the plurality of touch electrodes.

The touch sensing circuit can perform touch sensing using a self-capacitance sensing method or a mutual-capacitance sensing method.

If the touch sensing circuit performs touch sensing using a self-capacitance sensing method, the touch sensing circuit can perform touch sensing based on the capacitance between each touch electrode and a touch object (e.g., finger, pen, etc.). According to the self-capacitance sensing method, each of the plurality of touch electrodes can serve as a driving touch electrode and a sensing touch electrode. The touch driving circuit can drive all or part of the plurality of touch electrodes and sense all or part of the plurality of touch electrodes.

If the touch sensing circuit performs touch sensing using the mutual-capacitance sensing method, the touch sensing circuit can perform touch sensing based on the capacitance between touch electrodes. According to the mutual-capacitance sensing method, the plurality of touch electrodes can be divided into driving touch electrodes and sensing touch electrodes. The touch driving circuit can drive driving touch electrodes and sense sensing touch electrodes.

The touch driving circuit and the touch controller included in the touch sensing circuit can be implemented as separate devices or as one device. Additionally, the touch driving circuit and the data driving circuit can be implemented as separate devices or as one device.

The display device 100 can further include a power supply circuit which supplies various types of power to the display driving circuit and/or the touch sensing circuit.

The display device 100 according to embodiments of the present disclosure can be a mobile terminal such as a smart phone or tablet, or a monitor or television of various sizes, or a display of a vehicle, a building, or appliances, but is not limited thereto, and can be a display of various types and sizes capable of displaying information or images.

The display device 100 according to embodiments of the present disclosure can further include an electronic device such as a camera (e.g., image sensor) and a detection sensor. For example, the detection sensor can be a sensor for detecting an object or a human body by receiving light such as infrared, ultrasonic, or ultraviolet rays.

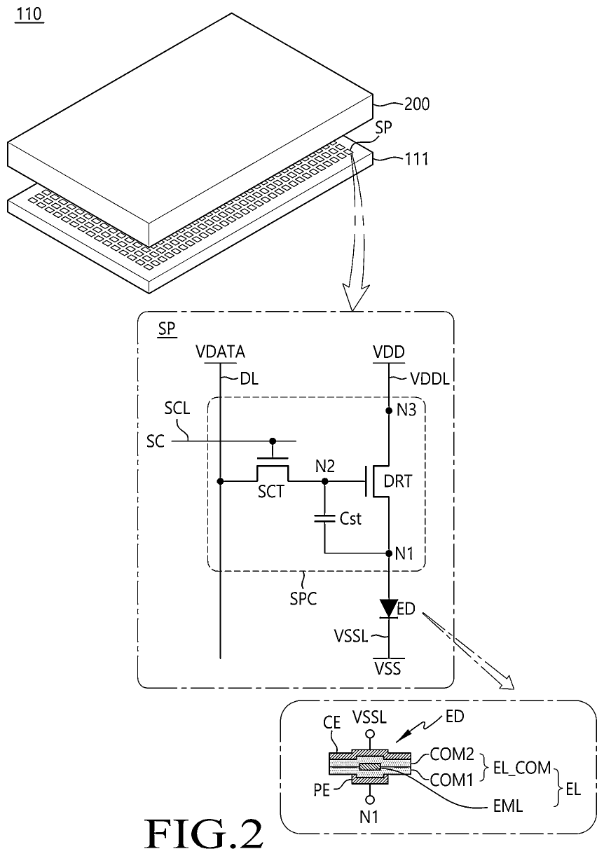

FIG. 2 illustrates a display panel 110 according to embodiments of the present disclosure.

Referring to FIG. 2, the display panel 110 can include a substrate 111 disposed in a plurality of subpixels SP and an encapsulation layer 200 on the substrate 111. Here, the encapsulation layer 200 can also be referred to as an encapsulation substrate or an encapsulation portion.

When the display device 100 according to embodiments of the present disclosure is a self-luminous display device, each of the plurality of subpixels SP can include a light emitting device ED and a subpixel circuit SPC for driving the light emitting device ED.

The subpixel circuit SPC can include a plurality of pixel driving transistors and at least one capacitor for driving the light emitting device ED. In the present disclosure, the subpixel circuit SPC can drive the light emitting device ED by supplying a driving current to the light emitting device ED at a predetermined timing. The light emitting device ED can be driven by a driving current and emit light.

The plurality of pixel driving transistors can include a driving transistor DRT for driving the light emitting device ED, and a scan transistor SCT which is turned on or off depending on the scan signal SC.

The driving transistor DRT can supply driving current to the light emitting device ED.

The scan transistor SCT can be configured to control the electrical state of a corresponding node (e.g., second node N2) in the subpixel circuit SPC or to control the state or operation of the driving transistor DRT.

At least one capacitor can include a storage capacitor Cst to maintain a constant voltage during a set period (e.g., a frame).

In order to drive the subpixel SP, a data signal VDATA which is an image signal, and a scan signal SC which is a gate signal can be applied to the subpixel SP. In addition, a common pixel driving voltage including a first common driving voltage VDD and a second common driving voltage VSS can be applied to the subpixel SP in order to drive the subpixel SP.

The light emitting device ED can include a pixel electrode PE, an intermediate layer EL, and a common electrode CE. The intermediate layer EL can be located between the pixel electrode PE and the common electrode CE.

For example, the pixel electrode PE can be an anode AND, and the common electrode CE can be a cathode CAT. Alternatively, the pixel electrode PE can be a cathode CAT and the common electrode CE can be an anode AND. Hereinafter, for convenience of explanation, it is exemplified a case where the pixel electrode PE is an anode AND and the common electrode CE is a cathode CAT.

In the case that the light emitting device ED is an organic light emitting diode, the intermediate layer EL can include an emission layer EML, a first common intermediate layer COM1 between the anode AND and the emission layer EML, and a second common intermediate layer COM2 between the emission layer EML and the cathode CAT. The first common intermediate layer COM1 and the second common intermediate layer COM2 can be collectively referred to as the common intermediate layer EL_COM. At least one of the first common intermediate layer COM1 and the second common intermediate layer COM2 can be omitted, depending on the design.

The emission layer EML can be disposed in each subpixel SP. In comparison, the common intermediate layer EL_COM can be commonly disposed across a plurality of subpixels SP. Embodiments are not limited thereto. As an example, the emission layer EML may be commonly disposed across a plurality of subpixels SP. As an example, the common intermediate layer EL_COM can be disposed in each subpixel SP.

The emission layer EML can be disposed in each emission area, and the common intermediate layer EL_COM can be commonly disposed across a plurality of emission areas and non-emission areas.

For example, the first common intermediate layer COM1 can include a hole injection layer HIL and/or a hole transport layer HTL, without being limited thereto. The second common intermediate layer COM2 can include an electron transport layer ETL and/or an electron injection layer EIL, without being limited thereto.

The hole injection layer can inject holes from the pixel electrode PE to the hole transport layer, the hole transport layer can transport holes to the emission EML, the electron injection layer can inject electrons from the common electrode CE to the electron transport layer, and the electron transport layer can transport electrons to the emission layer EML.

For example, the common electrode CE can be electrically connected to a second common driving voltage line VSSL. A second common driving voltage VSS, which is a type of common pixel driving voltage, can be applied to the common electrode CE through the second common driving voltage line VSSL. The pixel electrode PE can be electrically connected directly or indirectly (via another transistor) to the first node N1 of the driving transistor DRT of each subpixel SP. In the present disclosure, the second common driving voltage VSS can also be referred to as a base voltage VSS, and the second common driving voltage line VSSL can also be referred to as a base voltage line VSSL.

Each light emitting device ED can be composed of overlapping parts of the pixel electrode PE, the intermediate layer EL and the common electrode CE. A predetermined emissoin area can be formed by each light emitting device ED. For example, the emission area of each light emitting device ED can include an area where the pixel electrode PE, the intermediate layer EL and the common electrode CE overlap.

For example, the light emitting device ED can be an organic light emitting diode (OLED), an inorganic light emitting diode, a micro light emitting diode or a quantum dot light emitting device. For example, in the case that the light emitting device ED is an organic light emitting diode OLED, the intermediate layer EL in the light emitting device ED can include an organic intermediate layer EL containing an organic material.

The driving transistor DRT can be a driving transistor for supplying driving current to the light emitting device ED. The driving transistor DRT can be connected between a first common driving voltage line VDDL and the light emitting device ED.

The driving transistor DRT can include a first node N1, a second node N2, and a third node N3. The first node N1 can be electrically connected to the light emitting device ED. The data signal VDATA can be applied to the second node N2. The first common driving voltage VDD can be applied to the third node N3 from the first common driving voltage line VDDL.

In the driving transistor DRT, the second node N2 can be a gate node, the first node N1 can be a source node or a drain node, and the third node N3 can be a drain node or a source node. Hereinafter, for convenience of explanation, it will be described a case in which the second node N2 is a gate node (or gate electrode), the first node N1 is a source node (or source electrode, and the third node N3 is a drain node (or drain electrode) in the driving transistor DRT, however embodiments of the present disclosure are not limited thereto.

The scan transistor SCT included in the subpixel circuit SPC illustrated in FIG. 2 can be a switching transistor for transmitting a data signal VDATA, which is an image signal, to the second node N2 which is the gate node of the driving transistor DRT.

The scan transistor SCT can be controlled on-off by the scan signal SC which is a gate signal applied through the scan line SCL as a type of gate line GL, and can control the electrical connection between the second node N2 of the driving transistor DRT and the data line DL. The drain electrode or source electrode of the scan transistor SCT can be electrically connected to the data line DL, and the source electrode or drain electrode of the scan transistor SCT can be electrically connected to the second node N2 of the driving transistor DRT. The gate electrode of the scan transistor SCT can be electrically connected to the scan line SCL.

The storage capacitor Cst can be electrically connected between the first node N1 and the second node N2 of the driving transistor DRT. The storage capacitor Cst can include a first capacitor electrode electrically connected to the first node N1 of the driving transistor DRT or corresponding to the first node N1 of the driving transistor DRT, and a second capacitor electrode electrically connected to the second node N2 of the driving transistor DRT or corresponding to the second node N2 of the driving transistor DRT.

The storage capacitor Cst can be an external capacitor intentionally designed outside the driving transistor DT rather than a parasitic capacitor (e.g., Cgs, Cgd) as an internal capacitor which can exist between the first node N1 and the second node N2 of the driving transistor DRT.

Each of the driving transistor DRT and the scan transistor SCT can be an n-type transistor or a p-type transistor.

The display panel 110 can have a top emission structure that emits light in the front direction, or a bottom emission structure that emits light in the rear direction, or a dual emission structure that emits light in the front direction and the rear direction. Here, the front direction can correspond to the direction from the substrate 111 toward the encapsulation layer 200, and the rear direction can correspond to the direction from the encapsulation layer 200 toward the substrate 111.

If the display panel 110 has a top emission structure, at least a portion of the subpixel circuit SPC can overlap with or not overlap with at least a portion of the light emitting device ED in the vertical direction. Accordingly, the area of the emission area can be increased and the aperture ratio can be increased.

If the display panel 110 has a bottom emission structure, the subpixel circuit SPC may not overlap with the light emitting device ED in the vertical direction.

If the display panel 110 has a top emission structure, the pixel electrode PE can be a reflective electrode and the common electrode CE can be a transparent electrode. If the display panel 110 has a bottom emitting structure, the pixel electrode PE can be a transparent electrode and the common electrode CE can be a reflective electrode.

The subpixel circuit SPC can have 2T-1C structure including two transistors T1 and T2 and one capacitor Cst. In some case, the subpixel circuit SPC can further include one or more transistors or one or more capacitors.

For example, the subpixel circuit SPC can have a 8T-1C structure including eight transistors and a single capacitor. For another example, the subpixel circuit SPC can have a 6T-2C structure including six transistors and two capacitors. For another example, the subpixel circuit SPC can have a 7T-1C structure including seven transistors and one capacitor. These are only examples of subpixel circuits SPC, and are not limited thereto.

Depending on the structure of the subpixel circuit SPC, there can vary the type and number of gate signal supplied to the subpixel SP and/or gate lines. In addition, depending on the structure of the subpixel circuit SPC, there can vary the type and number of common driving voltages supplied to the subpixel SP.

Since circuit elements within each subpixel SP (in particular, light emitting devices EDs implemented with organic light emitting diodes (OLEDs) containing organic materials) are vulnerable to external moisture or oxygen, an encapsulation layer 200 can be disposed on the display panel 110 to reduce or prevent oxygen from penetrating into the circuit elements (particularly, the light emitting device ED).

The encapsulation layer 200 can be configured in various shapes to reduce or prevent the light emitting device ED from coming into contact with moisture or oxygen. For example, the encapsulation layer 200 can be composed of two or more layers in which organic layers and inorganic layers are alternately stacked, but embodiments of the present disclosure are not limited thereto.

In order to sense a touch of an user, the display device 100 according to embodiments of the present disclosure can include a touch sensor layer including a plurality of sensor electrodes, a touch driving circuit configured to sense a plurality of sensor electrodes, and a touch controller configured to determine the presence or absence of a touch or touch coordinates using the sensing results (e.g., touch sensing data) of the touch driving circuit.

The touch sensor layer can be built or embedded into the display panel 110.

The display panel 110 can further include a plurality of touch pads to which the touch sensing circuit is electrically connected, and a plurality of touch lines for electrically connecting a plurality of sensor electrodes included in the touch sensor layer and a plurality of touch pads to which the touch sensing circuit is connected.

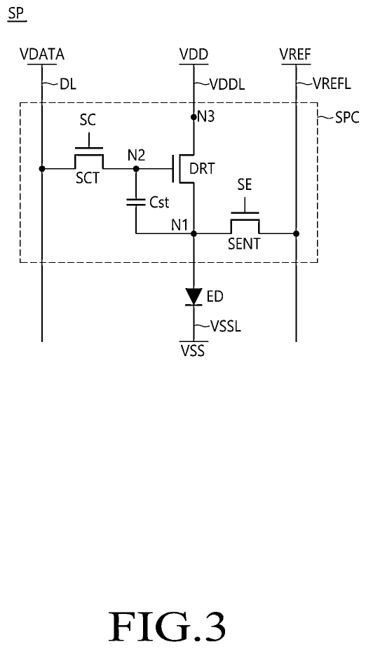

FIG. 3 illustrates a subpixel SP of a display panel 110 according to embodiments of the present disclosure.

Referring to FIG. 3, each of the plurality of subpixels SP disposed on the display panel 110 according to embodiments of the present disclosure can include a light emitting device ED and a subpixel circuit SPC for driving the light emitting device ED.

The subpixel circuit SPC of each subpixel SP illustrated in FIG. 3 can further include a sensing transistor SENT compared to a subpixel SP shown in FIG. 2. That is, the subpixel circuit SPC of each subpixel SP illustrated in FIG. 3 can include a driving transistor DRT, a scan transistor SCT, a sensing transistor SENT, and a storage capacitor Cst.

The light emitting device ED can include a pixel electrode PE, a common electrode CE, and an intermediate layer EL located between the pixel electrode PE and the common electrode CE. A first common driving voltage line VSSL can be electrically connected to the common electrode CE.

The driving transistor DRT is a transistor for driving the light emitting device ED, and can include a first node N1, a second node N2, and a third node N3.

The first node N1 of the driving transistor DRT can be a source node or a drain node of the driving transistor DRT, can be electrically connected to the source node or drain node of the sensing transistor SENT, and can also be electrically connected to the pixel electrode PE of light emitting device ED.

The second node N2 of the driving transistor DRT can be a gate node of the driving transistor DRT, and can be electrically connected to the source node or drain node of the scan transistor SCT.

The third node N3 of the driving transistor DRT can be electrically connected to the first common driving voltage line VDDL which supplies the first common driving voltage VDD.

The scan transistor SCT can be controlled by a scan signal SC, which is a type of gate signal, and can be connected between the second node N2 of the driving transistor DRT and the data line DL. That is, the scan transistor SCT can be turned on or turned off according to the scan signal SC supplied from the scan signal line, which is a type of gate line GL, and can control the connection between the data line DL and the second node N2 of the driving transistor DRT.

The scan transistor SCT can be turned on by the scan signal SC having a turn-on level voltage, and can apply the data voltage VDATA supplied from the data line DL to the second node N2 of the driving transistor DRT.

Here, if the scan transistor SCT is an n-type transistor, the turn-on level voltage of the scan signal SC can be a high-level voltage. If the scan transistor SCT is a p-type transistor, the turn-on level voltage of the scan signal SC can be a low-level voltage. Hereinafter, the scan transistor SCT is exemplified as an n-type transistor. Accordingly, the turn-on level voltage is exemplified as a high-level voltage.

Referring to FIG. 3, the sensing transistor SENT can be controlled by a sensing signal SE, which is a type of gate signal, and can be connected between the first node N1 of the driving transistor DRT and a reference voltage line VREF). That is, the sensing transistor SENT can be turned on or turned off according to the sensing signal SE supplied from the sensing signal line, which is another type of gate line GL, and can control the connection between the reference voltage line VREFL and the first node N1 of the driving transistor DRT.

The sensing transistor SENT can be turned on by the sensing signal SE having a turn-on level voltage, and can transfer the reference voltage VREF supplied from the reference voltage line VREFL to the first node N1 of the driving transistor DRT. Here, the sensing signal SE can be considered as a second scan signal different from the scan signal SC.

In addition, the sensing transistor SENT can be turned on by the sensing signal SE having a turn-on level voltage, and can transfer the voltage of the first node N1 of the driving transistor DRT to the reference voltage line VREFL.

Here, when the sensing transistor SENT is an n-type transistor, the turn-on level voltage of the sensing signal SE can be a high-level voltage. When the sensing transistor SENT is a p-type transistor, the turn-on level voltage of the sensing signal SE can be a low-level voltage. Hereinafter, for example, there is exemplified the sensing transistor SENT is an n-type transistor, and accordingly, the turn-on level voltage is a high-level voltage.

The function of the sensing transistor SENT to transfer the voltage of the first node N1 of the driving transistor DRT to the reference voltage line VREFL can be used when driving to sense the characteristic value of the subpixel SP. In this case, the voltage transferred to the reference voltage line VREFL can be a voltage for calculating the characteristic value of the subpixel SP or a voltage reflecting the characteristic value of the subpixel SP.

In the present disclosure, the characteristic value of the subpixel SP can be the characteristic value of the driving transistor DRT or the light emitting device ED. For example, the characteristic values of the driving transistor DRT can include a threshold voltage and a mobility of the driving transistor DRT. The characteristic value of the light emitting device ED can include a threshold voltage of the light emitting device ED.

The storage capacitor Cst can be connected between the second node N2 and the first node N1 of the driving transistor DRT. The storage capacitor Cst can be charged with a charge corresponding to the voltage difference between the two ends, and can play the role of maintaining the voltage difference between the two ends for a set frame time. Accordingly, the corresponding subpixel SP can emit light during the set frame time.

For example, the gate node of the scan transistor SCT and the gate node of the sensing transistor SENT may not be connected. That is, the gate node of the scan transistor SCT and the gate node of the sensing transistor SENT can be connected to different gate lines GL. In this case, on-off of the scan transistor SCT and on-off of the sensing transistor SENT can be controlled independently.

As another example, the gate node of the scan transistor SCT and the gate node of the sensing transistor SENT can be electrically connected to each other. That is, the gate node of the scan transistor SCT and the gate node of the sensing transistor SENT can be commonly connected to one gate line GL. In this case, the on-off of the scan transistor SCT and the on-off of the sensing transistor SENT can be controlled simultaneously.

The driving transistor DRT, scan transistor SCT, and sensing transistor SENT can each be an n-type transistor or a p-type transistor. In this disclosure, for convenience of explanation, it is exemplified that the driving transistor DRT, scan transistor SCT, and sensing transistor SENT are each n-type.

The subpixel SP shown in FIG. 3 is only an example, and can be modified in various ways by including one or more transistors or one or more capacitors.

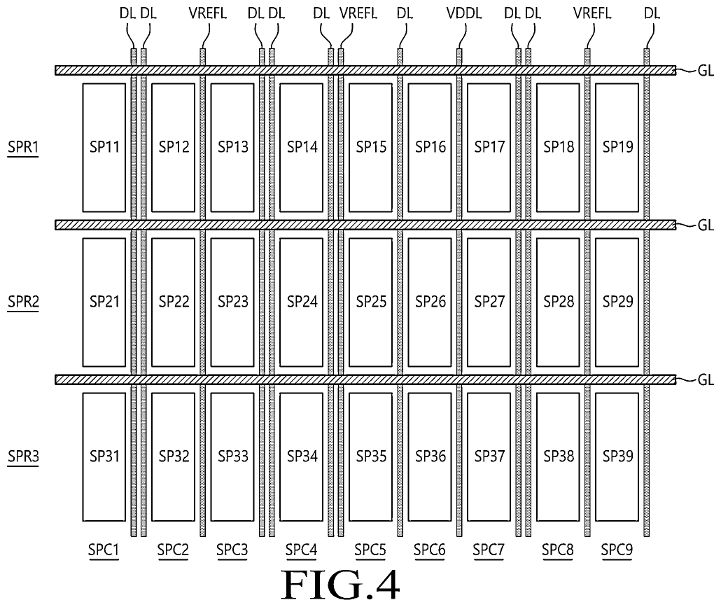

FIG. 4 is a plan view of a display panel 110 according to embodiments of the present disclosure.

Referring to FIG. 4, a plurality of subpixels SP disposed on the display panel 110 according to embodiments of the present disclosure can be arranged in a matrix form. For example, the plurality of subpixels SP disposed on the display panel 110 according to embodiments of the present disclosure can include 27 subpixels SP11 to SP19, SP21 to SP29 and SP31 to SP39 arranged in three rows and nine columns. The 27 subpixels SP11 to SP19, SP21 to SP29, and SP31 to SP39 can constitute the first to third subpixel rows SPR1 to SPR3. The 27 subpixels SP11 to SP19, SP21 to SP29, and SP31 to SP39 can constitute the first to ninth subpixel columns SPC1 to SPC9.

As an example, the plurality of subpixels SP disposed on the display panel 110 can include a red subpixel emitting red light, a green subpixel emitting green light, and a blue subpixel emitting blue light. Embodiments are not limited thereto. As an example, a subpixel emitting light of other color such as cyan, yellow, magenta, etc. can be alternatively or additionally included.

For example, in this case, subpixels arranged in the first, fourth, and seventh subpixel columns SPC1, SPC4, and SPC7 can be red subpixels. Subpixels arranged in the second, fifth, and eighth subpixel columns SPC2, SPC5, and SPC8 can be green subpixels. Subpixels arranged in the third, sixth, and ninth subpixel columns SPC3, SPC6, and SPC9 can be green subpixels.

As an example, the plurality of subpixels SP disposed on the display panel 110 can include a red subpixel emitting red light, a green subpixel emitting green light, a blue subpixel emitting blue light, and a white subpixel emitting white light.

The display panel 110 according to embodiments of the present disclosure can include vertical lines extending in the column direction and horizontal lines extending in the row direction. The horizontal and vertical lines can vary depending on the structure of the subpixel SP.

The horizontal lines can include the gate lines GL, and the vertical lines can include the data lines DL.

For example, in the case that the subpixel SP has the structure shown in FIG. 2, the horizontal lines can include scan signal lines as gate lines GL, and the vertical lines can include data lines DL and at least one first common driving voltage line VDDL.

As another example, if the subpixel SP is configured as the structure shown in FIG. 3, the horizontal lines can include scan signal lines and sensing signal lines as gate lines GL, and the vertical lines can include data lines DL, at least one first common driving voltage line VDDL, and at least one reference voltage line VREFL.

FIG. 4 illustrates a signal line arrangement structure for a case in which the subpixel SP has the same structure as that of FIG. 3. The arrangement positions and numbers of the gate lines GL, data lines DL, at least one first common driving voltage line VDDL, and at least one reference voltage line VREFL illustrated in FIG. 4 can be modified in various ways.

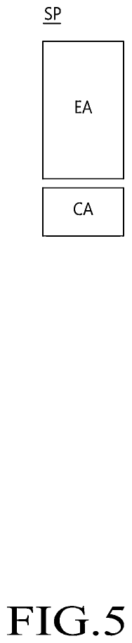

FIG. 5 illustrates an area of a subpixel of a display panel 110 according to embodiments of the present disclosure.

Referring to FIG. 5, in the case that the display panel 110 according to embodiments of the present disclosure emits light in a rear direction, the area of each subpixel SP can include a circuit area where the subpixel circuit SPC is disposed, and an emission area EA where light is emitted by the light emitting device ED.

In the case that the display panel 110 emits light in the rear direction, the circuit area CA and the emission area EA may not overlap each other. The emission area EA can be also referred to as an opening or aperture area.

Meanwhile, light generated from the emission layer EML of the light emitting device ED of the display panel 110 can pass through various components within the display panel 110 and comes out of the display panel 110. However, among the light generated in the emission layer EML of the light emitting device ED, there can be light that does not come out of the display panel 110 and is trapped inside the display panel 110.

Among the light generated in the emission layer EML of the light emitting device ED, as more light does not come out of the display panel 110 and is trapped inside the display panel 110, the luminance of the corresponding subpixel SP can decrease. Accordingly, there can deteriorate the quality of the image displayed on the display panel 110.

Accordingly, the display panel 110 according to embodiments of the present disclosure can include a light extraction structure which allows a greater amount of light to be emitted toward the viewing surface among the light generated by the light emitting device ED.

The light extraction structure according to embodiments of the present disclosure can be a structure included in the display panel 110, and can reduce the amount of light trapped inside the display panel 110 among the amount of light generated from the emission layer EML of the light emitting device ED in the display panel 110 and increase the amount of light emitted to the outside of the display panel 110. “Light extraction” in the embodiments of the present disclosure can mean that a portion of the light emitted from the emission layer EML of the light emitting device ED in the display panel 110 is emitted to the outside of the display panel 110.

Hereinafter, it will be described a light extraction structure according to embodiments of the present disclosure in detail. In the following description, it is exemplified a case where the display panel 110 according to embodiments of the present disclosure has a bottom emission structure.

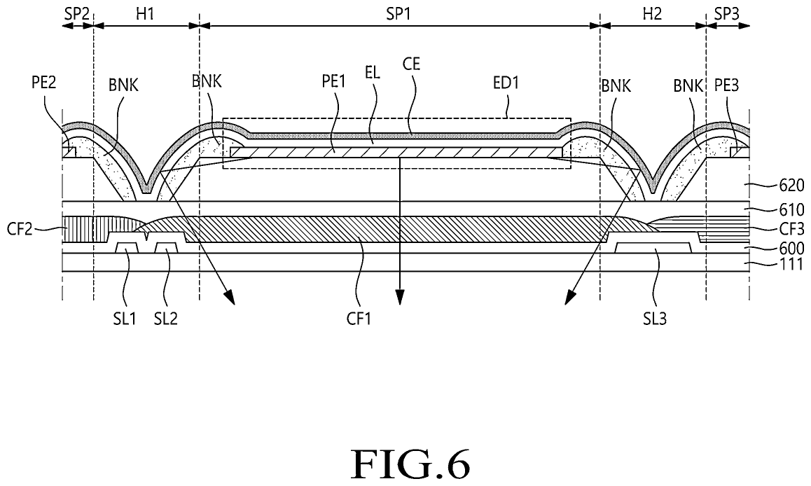

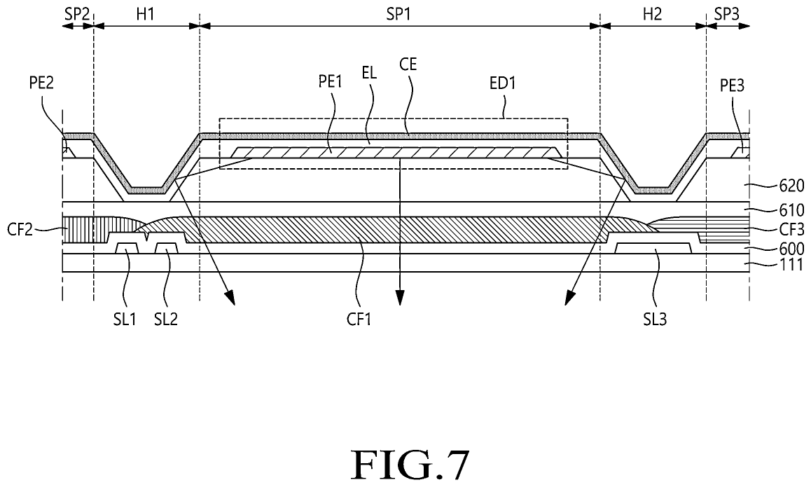

FIGS. 6 and 7 illustrate a light extraction structure of a display panel 110 according to embodiments of the present disclosure.

Particularly, FIG. 6 illustrates a light extraction structure in the display panel 110 including a bank BNK, and FIG. 7 illustrates a light extraction structure in the display panel 110 without a bank BNK.

Referring to FIGS. 6 and 7, the display panel 110 can include a first subpixel SP1, a second subpixel SP2 on one side of the first subpixel SP1, and a third subpixel SP3 on the other side of the first subpixel SP1.

The display panel 110 according to embodiments of the present disclosure can include a substrate 111, a passivation layer 600 on the substrate 111, first to third color filters CF1, CF2 and CF3 on the passivation layer 600, a first protective layer 610 on the first to third color filters CF1, CF2 and CF3, a second protective layer 620 located on the first protective layer 610, first to third pixel electrodes PE1, PE2 and PE3 located on the second protective layer 620, an intermediate layer EL on the first to third pixel electrodes PE1, PE2 and PE3, and a common electrode CE on the intermediate layer EL.

The first to third pixel electrodes PE1, PE2 and PE3 can be transparent electrodes, and the common electrode CE can be a reflective electrode.

The display panel 110 according to embodiments of the present disclosure can include signal lines SL1, SL2 and SL3. As an example, at least one of or all of the signal lines SL1, SL2 and SL3 may be located between the substrate 111 and the passivation layer 600. For example, the signal lines SL1, SL2 and SL3 can be vertical lines. For example, the vertical lines can include data lines DL, at least one first common driving voltage line VDDL, and at least one reference voltage line VREFL.

Further, holes H1 and H2 can be formed between two adjacent subpixels (or two adjacent pixel electrodes) in the second protective layer 620. That is, the second protective layer 620 can include a first hole H1 formed between the first subpixel SP1 and the second subpixel SP2, a second hole H2 formed between the second subpixel SP2 and the third subpixel SP3.

Accordingly, the intermediate layer EL and the common electrode CE can be disposed inside the holes H1 and H2 along the sides of the holes H1 and H2 of the second protective layer 620. Accordingly, a portion of the common electrode CE disposed inside the holes H1 and H2 of the second protective layer 620 can be located closer to the substrate 111 than the pixel electrodes PE1, PE2 and PE3.

Therefore, the light emitted from the emission layer EML of the first light emitting device ED1 in the first subpixel SP1 can be reflected at the common electrode CE and can travel toward the viewing surface. Here, the emission layer EML of the first light emitting device ED1 can be a layer included in the intermediate layer EL, and can exist between the first pixel electrode PE1 and the common electrode CE (see FIG. 2).

Referring to FIG. 6, a bank BK can be disposed between the pixel electrodes PE1, PE2 and PE3 and the intermediate layer EL. As an example, the bank BK can be disposed to cover the ends of the pixel electrodes PE1, PE2 and PE3, without being limited thereto. As an example, the bank BK can be disposed to contact the ends of the pixel electrodes PE1, PE2 and PE3, without covering the ends of the pixel electrodes PE1, PE2 and PE3. In addition, the bank BK can have grooves or holes formed inside the holes H1 and H2 of the second protective layer 620. Accordingly, a portion of the common electrode CE disposed inside the holes H1 and H2 of the second protective layer 620 can be located closer to the substrate 111 than the pixel electrodes PE1, PE2 and PE3. As an example, the bank BK may have grooves or holes formed inside the holes H1 and H2 of the second protective layer 620, to expose the second protective layer 620, or not to expose the second protective layer 620. As an example, the bank BK may have grooves or holes formed inside the holes H1 and H2 of the second protective layer 620 to disconnect or to not disconnect the bank BK at the holes H1 and H2 of the second protective layer 620. As an example, the bank BK may have grooves or holes formed inside the holes H1 and H2 of the second protective layer 620, such that the bottom surface of the grooves or holes may be lower than the pixel electrodes PE1, PE2 and PE3, without being limited thereto.

If a bank BNK exists, the sides of both ends of each pixel electrode PE1, PE2 and PE3 can have various shapes such as a reverse taper shape, a regular (normal) taper shape, or a vertical shape.

As shown in FIG. 7, the bank BNK may not exist. Referring to FIG. 7, when the bank BNK does not exist, the side surfaces of both ends of each pixel electrode PE1, PE2, and PE3 can have a regular taper shape. As a result, it is possible to reduce or prevent charges from being concentrated on both ends of each pixel electrode (PE1, PE2 and PE3). Embodiments are not limited thereto. As an example, the side surfaces of both ends of each pixel electrode PE1, PE2, and PE3 can have various shapes such as a reverse taper shape, a regular normal taper shape, or a vertical shape, even when the bank BNK does not exist.

In the case that the bank BNK does not exist, if the sides of both ends of each pixel electrode PE1, PE2 and PE3 have a reverse taper shape or vertical shape where sharp points can exist, the charges can be concentrated on both ends of each pixel electrode PE1, PE2 and PE3. If charges are concentrated on both ends (e.g., edges) of each pixel electrode PE1, PE2 and PE3, there can occur more severe deterioration in the portion adjacent to both ends of each pixel electrode PE1, PE2 and PE3 in the intermediate layer EL. As a result, the luminance of the outer portion of the emission area of each subpixel SP1, SP2, and SP3 can become abnormally low.

Therefore, in the case that the bank BNK does not exist, the sides of both ends of each pixel electrode PE1, PE2, and PE3 can have a regular taper shape, so that it is possible to reduce or prevent the phenomenon of electric charges being concentrated. As a result, it is possible to reduce or prevent the phenomenon in which the luminance of the outer portion of the emission area of each subpixel SP1, SP2 and SP3 becomes abnormally low or dark.

As described above, the light extraction structure of the display panel 110 according to embodiments of the present disclosure can have the following characteristics.

The insulating layer (e.g., the second protective layer 620 in FIGS. 6 and 7) located below the pixel electrode PE can have a step structure (e.g., a hole or groove in the insulating layer). The step structure of the insulating layer can be located between two adjacent pixel electrodes PE. That is, the step structure of the insulating layer may not overlap with the pixel electrode PE. In addition, the common electrode CE can be also disposed inside the hole or groove as the step structure of the insulating layer, so that the common electrode CE located inside the hole or groove of the insulating layer can be located lower than the emission layer EML or the pixel electrode PE.

According to the light extraction structure of the display panel 110 according to embodiments of the present disclosure, the light emitted from the emission layer EML of the light emitting device ED can be reflected by the common electrode CE located on the side of the pixel electrode PE and travel toward the viewing surface.

Accordingly, the ratio of light emitted to the outside of the display panel 110 among the light emitted from the emission layer EML of the light emitting device ED can increase. That is, light extraction performance can be increased.

The display panel 110 according to embodiments of the present disclosure can have a light extraction structure, thereby increasing light extraction efficiency. The light extraction efficiency can indicate a degree of the increase of the amount of light emitted outside the display panel 110 in a case having a light extraction structure compared to the amount of light emitted outside the display panel 110 in a case without light extraction structure.

A light extraction structure can be formed by forming a step structure of the second protective layer 620 between two adjacent emission areas (i.e., adjacent subpixels).

In the case that the display panel 110 is required to be designed as a high-resolution product, a gap between two adjacent emission areas (i.e., two adjacent subpixels) can become significantly narrowed. Accordingly, there can be insufficient space for a light extraction structure to be formed between two adjacent emission areas (i.e., two adjacent subpixels).

Accordingly, the display device 100 according to embodiments of the present disclosure can include a light extraction structure suitable for the high-resolution display panel 110. Hereinafter, it will be described in detail a light extraction structure suitable for the high-resolution display panel 110 according to embodiments of the present disclosure. Hereinafter, “light extraction structure suitable for the high-resolution display panel 110” is described as “light extraction structure for high-resolution.”

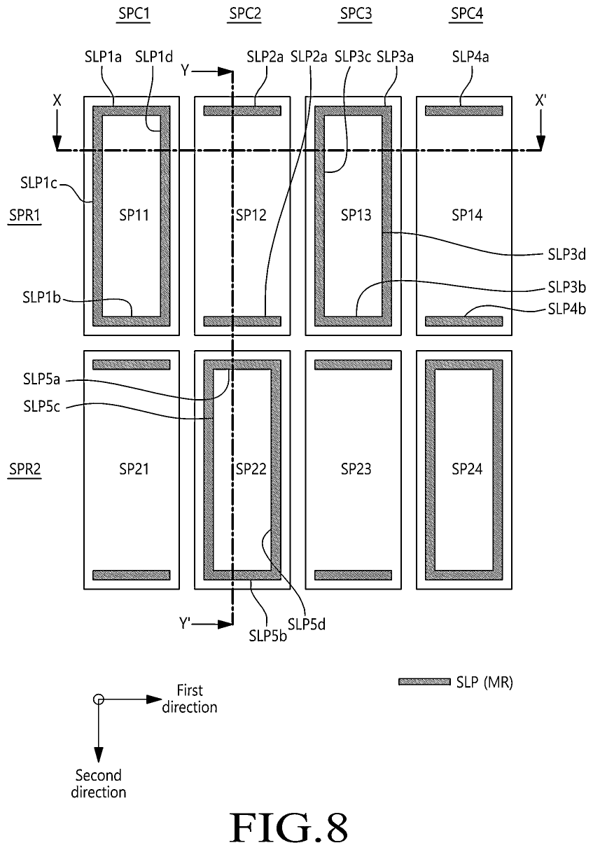

FIGS. 8 to 12 illustrate a light extraction structure for high-resolution of the display panel 110 according to embodiments of the present disclosure.

Referring to FIG. 8, the display panel 110 having a light extraction structure for high-resolution according to embodiments of the present disclosure can include eight subpixels SP11, SP12, SP13, SP14, SP21, SP22, SP23 and SP24.

Eight subpixels SP11, SP12, SP13, SP14, SP21, SP22, SP23 and SP24 can constitute a first subpixel row SPR1 and a second subpixel row SPR2. Eight subpixels SP11, SP12, SP13, SP14, SP21, SP22, SP23 and SP24 can constitute the first to fourth subpixel columns SPC1 to SPC4. In FIG. 8, each of the eight subpixels SP11, SP12, SP13, SP14, SP21, SP22, SP23 and SP24 can mean a subpixel area.

In FIG. 8, for convenience of explanation, there are not illustrated various signal lines (e.g., DL, VDDL, REFL, GL) for driving eight subpixels SP11, SP12, SP13, SP14, SP21, SP22, SP23 and SP24. In FIG. 8, the rectangles representing the eight subpixels SP11, SP12, SP13, SP14, SP21, SP22, SP23 and SP24 can represent the emission areas of the eight subpixels SP11, SP12, SP13, SP14, SP21, SP22, SP23 and SP24. However, the emission areas of the eight subpixels SP11, SP12, SP13, SP14, SP21, SP22, SP23 and SP24 can have various shapes other than a rectangle shape, such as a circular shape, an oval shape, a rhombus, a polygonal shape, etc., without being limited thereto. In FIG. 8, the circuit areas of eight subpixels SP11, SP12, SP13, SP14, SP21, SP22, SP23 and SP24 are omitted.

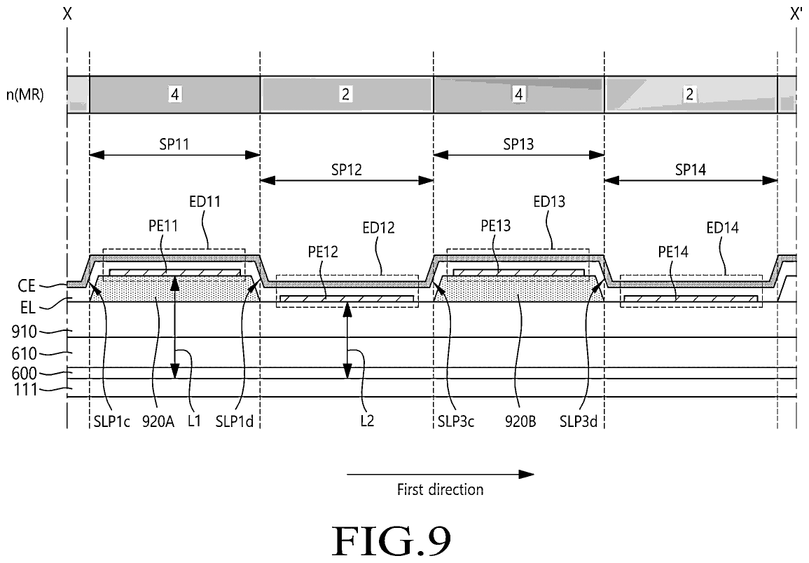

In FIGS. 9 to 12, color filters disposed between the passivation layer 600 and the first protective layer 610 are omitted. Each color filter can be disposed to overlap with the corresponding pixel electrode (see FIGS. 6 and 7).

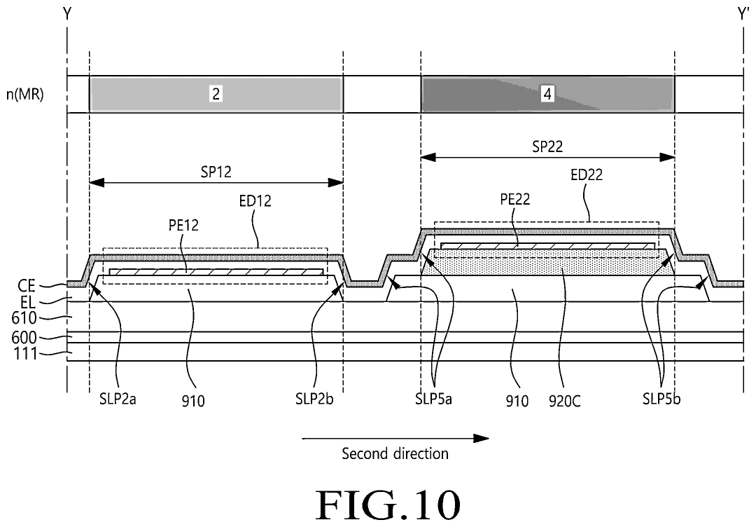

In addition, the display panel 110 according to embodiments of the present disclosure can have a structure with a bank BNK as shown in FIG. 6, or can have a structure without a bank BNK as shown in FIG. 7. Referring to FIGS. 9 and 10, when the bank BNK exists as shown in FIG. 6, the bank BNK can be disposed to partially cover both ends of each pixel electrode.

Referring to FIG. 8, a light extraction structure for high-resolution included in the display panel 110 according to embodiments of the present disclosure can include a mirror MR (e.g., a reflector). The light extraction structure for high-resolution included in the display panel 110 according to embodiments of the present disclosure can include not only a structure referred to as a mirror MR, but also a number of mirrors n(MR) and a mirror arrangement structure.

The mirror MR for forming a light extraction structure for high-resolution according to embodiments of the present disclosure can be formed by an inclined surface SLP or a slope of the common electrode CE. In embodiments of the present disclosure, the inclined surface SLP of the common electrode CE can correspond to a step portion of the common electrode CE, and the inclined surface SLP of the common electrode CE can also be referred to as a mirror MR or a mirror surface.

In the light extraction structure for high-resolution according to embodiments of the present disclosure, the common electrode CE can have a plurality of inclined surfaces SLP.

For example, in a light extraction structure for high-resolution according to embodiments of the present disclosure, the number of inclined surfaces SLP of the common electrode CE existing in or around the area of some subpixels can be different from the number of inclined surfaces SLP of the common electrode CE existing in or around the area of some other subpixels.

As another example, in the light extraction structure for high-resolution according to embodiments of the present disclosure, a location of inclined surfaces SLP of the common electrode CE existing in or around the area of some subpixels can be different from a location of inclined surfaces SLP of the common electrode CE existing in or around the area of some other subpixels.

It will be described a light extraction structure suitable for high resolution according to embodiments of the present disclosure in more detail with reference to FIG. 8.

Referring to FIG. 8, a plurality of subpixels SP11 to SP14 and SP21 to SP24 can be arranged in a matrix form.

A plurality of subpixels SP11 to SP14, SP21 to SP24 can constitute a first subpixel row SPR1 and a second subpixel row SPR2, and can constitute a first subpixel column SPC1, a second subpixel column SPC2, a third subpixel column SPC3, and a fourth subpixel column SPC4.

The first subpixel row SPR1 can include a plurality of subpixels SP11, SP12, SP13, and SP14 arranged in a first direction (e.g., row direction). The second subpixel row SPR2 can include a plurality of subpixels SP21, SP22, SP23, and SP24 arranged in the first direction (e.g., row direction). The second subpixel row SPR2 can be disposed adjacent to the first subpixel row SPR1 in a second direction (e.g., column direction).

In each of the first subpixel row SPR1 and the second subpixel row SPR2, the number of mirrors n(MR) for each subpixel can be repeated at 4 and 2. That is, in each of the first subpixel row SPR1 and the second subpixel row SPR2, a subpixel (e.g., SP12) with a mirror number n(MR) of 2 can exist between subpixels (e.g., SP11, SP13) with a mirror number n(MR) of 4.

In the four subpixels SP11, SP12, SP13 and SP14 arranged in the first subpixel row SPR1, the number of mirrors n(MR) of subpixels SP11 and SP13 disposed in the odd subpixel columns SPC1 and SPC3 can be different from the number of mirrors n(MR) of the subpixels SP12 and SP14 arranged in the even subpixel columns SPC2 and SPC4.

For example, in the four subpixels SP11, SP12, SP13 and SP14 arranged in the first subpixel row SPR1, the number of mirrors n(MR) of subpixels SP11 and SP13 disposed in the odd subpixel columns SPC1 and SPC3 can be 4, and the number of mirrors n(MR) of the subpixels SP12 and SP14 arranged in the even subpixel columns SPC2 and SPC4 can be 2.

In the four subpixels SP21, SP22, SP23 and SP24 arranged in the second subpixel row SPR2, the number of mirrors n(MR) of subpixels SP21 and SP23 disposed in the odd subpixel columns SPC1 and SPC3 and the number of mirrors n(MR) of the subpixels SP22 and SP24 arranged in the even subpixel columns SPC2 and SPC4 can be different from each other.

For example, in the four subpixels SP21, SP22, SP23 and SP24 arranged in the second subpixel row SPR2, the number of mirrors n(MR) of subpixels SP21 and SP23 disposed in the odd subpixel columns SPC1 and SPC3 can be 2, and the number of mirrors n(MR) of the subpixels SP22 and SP24 arranged in the even subpixel columns SPC2 and SPC4 can be 4.

According to the above, in the first subpixel row SPR1, the number of mirrors n(MR) of the subpixel SP11 located in the first subpixel column SPC1 can be 4, the number of mirrors n(MR) of the subpixel SP12 located in the second subpixel column SPC2 can be 2, the number of mirrors n(MR) of the subpixel SP13 located in the third subpixel column SPC3 can be 4, and the number of mirrors n(MR) of the subpixel SP14 located in the fourth subpixel column SPC4 can be 2.

In addition, in the second subpixel row SPR2, the number of mirrors n(MR) of the subpixel SP21 located in the first subpixel column SPC1 can be 2, the number of mirrors n(MR) of the subpixel SP22 located in the second subpixel column SPC2 can be 4, the number of mirrors n(MR) of the subpixel SP23 located in the third subpixel column SPC3 can be 2, and the number of mirrors n(MR) of the subpixel SP24 located in the fourth subpixel column SPC4 can be 4.

A mirror MR can exist on each of the four sides of each of the subpixels SP11, SP13, SP22 and SP24 having the number of mirrors n(MR) of 4.

Two mirrors MR can exist on two sides facing each other in the first direction (e.g., column direction) among the four sides of each of the subpixels SP12, SP14, SP21, and SP23 having the number of mirrors n(MR) of 2.

The mirror MR is a surface on which light emitted from the light emitting device ED is reflected, and can correspond to the inclined surface SLP of the common electrode CE.

For example, the four mirrors MR of the subpixel SP11 in the first row and the first column can correspond to each of the four inclined surfaces SLP1a, SLP1b, SLP1c, and SLP1d of the common electrode CE surrounding the area or surrounding area of the subpixel SP11 in the first row and the first column. Two mirrors MR of the subpixels SP12 in the first row and second column can correspond to each of two inclined surfaces SLP2a and SLP2b of the common electrode CE facing each other in the first direction facing the area of the subpixel SP12 in the first row and second column or its surrounding area. The four mirrors MR of the subpixel SP13 in the first row and the third column may correspond to each of the four inclined surfaces SLP3a, SLP3b, SLP3c, and SLP3d of the common electrode CE surrounding the area or surrounding area of the subpixel SP13 in the first row and the third column. Two mirrors MR of the subpixels SP14 in the first row and fourth column can correspond to each of two inclined surfaces SLP4a and SLP4b of the common electrode CE facing each other in the first direction facing the area of the subpixel SP14 in the first row and fourth column or its surrounding area. The four mirrors MR of the subpixel SP22 in the second row and second column can correspond to each of the four inclined surfaces SLP5a, SLP5b, SLP5c and SLP5d of the common electrode CE surrounding the area or surrounding area of the subpixel SP22 in the second row and second column. Embodiments are not limited thereto. As an example, the number of mirrors MR of one subpixel is not limited to 2 or 4. As an example, the number of mirrors MR of one subpixel can be 0, 1, 2, 3, or more than 4. As an example, the number of mirrors MR of one subpixel may depends on a shape of the emission area of the one subpixel, without being limited thereto.

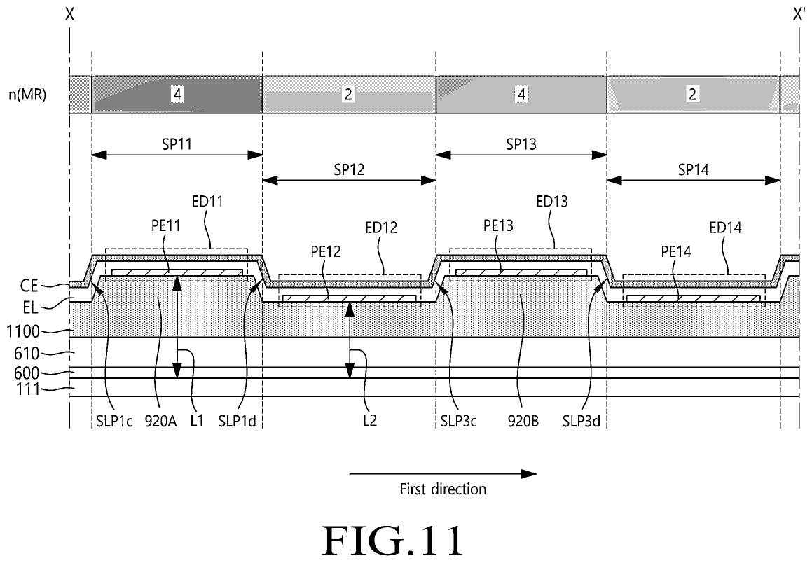

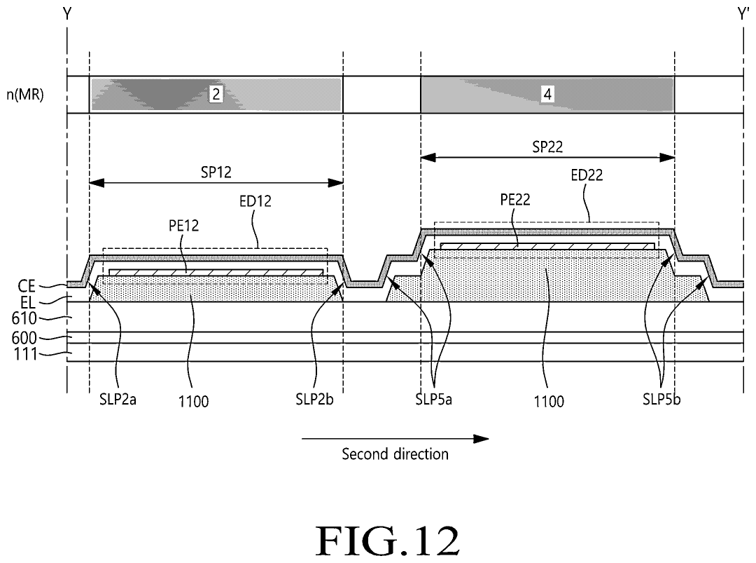

It will be described in more detail a light extraction structure for high resolution according to embodiments of the present disclosure with reference to FIGS. 9 to 12. First, it will be described with reference to FIGS. 9 and 10. FIGS. 11 and 12 can correspond to FIGS. 9 and 10, respectively.

Particularly, FIG. 9 is a cross-sectional view of an area X-X′ where the first to fourth subpixels SP11, SP12, SP13 and SP14 of the first subpixel row SPR1 in FIG. 8 are disposed. FIG. 10 is a cross-sectional view of an area Y-Y′ where the second subpixel SP12 and the fifth subpixel SP22 of the second subpixel column SPC2 in FIG. 8 are disposed.

Referring to FIGS. 9 and 10, the first subpixel SP11 can include a first light emitting device ED11, the second subpixel SP12 can include a second light emitting device ED12, the third subpixel SP13 can include a third light emitting device ED13, the fourth subpixel SP14 can include a fourth light emitting device ED14, and the fifth subpixel SP22 can include a fifth light emitting device ED22.

Referring to FIG. 9, the display panel 110 according to embodiments of the present disclosure can include, as the insulating layers for forming a light extraction structure for high-resolution, a first protective layer 610 on the substrate 111, a lower insulating layer 910 on the first protective layer 610, a first upper insulating layer 920A located on the lower insulating layer 910, and a second upper insulating layer 920B located on the lower insulating layer 910 and spaced apart from the first upper insulating layer 920A in a first direction.

The display panel 110 according to embodiments of the present disclosure can include a first pixel electrode PE11 located on the first upper insulating layer 920A, a second pixel electrode PE12 located on the lower insulating layer 910 and disposed between one side of the first upper insulating layer 920A and the other side of the second upper insulating layer 920B, a third pixel electrode PE13 located on the second upper insulating layer 920B, and a fourth pixel electrode PE14 located on the lower insulating layer 910 and disposed on one side of the second upper insulating layer 920B.

The display panel 110 according to embodiments of the present disclosure can further include, as an insulating layer for forming a light extraction structure for high-resolution, a third upper insulating layer 920C located on the lower insulating layer 910 and disposed on one side of the second pixel electrode PE12 in a second direction different from the first direction.

The display panel 110 according to embodiments of the present disclosure can further include a fourth pixel electrode PE14 located on the lower insulating layer 910 and disposed on one side of the second upper insulating layer 920B, and a fifth pixel electrode PE22 located on the third upper insulating layer 920C.

Referring to FIGS. 9 and 10, the first pixel electrode PE11, the second pixel electrode PE12, the third pixel electrode PE13, the fourth pixel electrode PE14, and the fifth pixel electrode PE22 can be included in the first subpixel SP11, the second subpixel SP12, the third subpixel SP13, the fourth subpixel SP14, and the fifth subpixel SP22, respectively.

Referring to FIGS. 8, 9, and 10, the first subpixel SP11, the second subpixel SP12, the third subpixel SP13 and the fourth subpixel SP14 can be arranged in a first subpixel row SPR1. The fifth subpixel SP22 can be arranged in a second subpixel row SPR2 adjacent to the first subpixel row SPR1 in a second direction, and the second subpixel SP12 and the fifth subpixel SP22 can be arranged in the second subpixel column SPC2.

The first upper insulating layer 920A and the second upper insulating layer 920B can be disposed in the first subpixel row SPR1, and the third upper insulating layer 920A can be disposed in the second subpixel row SPR2.

At least two of or each of the first upper insulating layer 920A, the second upper insulating layer 920B, and the third upper insulating layer 920C can be layers of the same insulating material. The first upper insulating layer 920A, the second upper insulating layer 920B, and the third upper insulating layer 920C can be disposed to be spaced apart from each other in an island shape.

Each of the first upper insulating layer 920A, the second upper insulating layer 920B, and the third upper insulating layer 920C can have a size corresponding to the emission area EA of the subpixel SP. As an example, at least two or all of the first upper insulating layer 920A, the second upper insulating layer 920B, and the third upper insulating layer 920C may have the same size, without being limited thereto. As an example, at least two or all of the first upper insulating layer 920A, the second upper insulating layer 920B, and the third upper insulating layer 920C may have the same height, without being limited thereto.

Referring to FIGS. 9 and 10, the display panel 110 according to embodiments of the present disclosure can include an intermediate layer EL located on a first pixel electrode PE11, a second pixel electrode PE12, a third pixel electrode PE13, the fourth pixel electrode PE14, and the fifth pixel electrode PE22, and a common electrode CE on the intermediate layer EL.

The intermediate layer EL can include the first to fifth emission layers (EML) and a common intermediate layer EL_COM. The first to fifth emission layers EML can be disposed to overlap the first to fifth pixel electrodes PE11, PE12, PE13, PE14 and PE15, respectively. The common intermediate layer EL_COM can include a first common intermediate layer COM1 and/or a second common intermediate layer COM2. The first common intermediate layer COM1 can be commonly disposed between the first to fifth pixel electrodes PE11, PE12, PE13, PE14 and PE15, and the first to fifth emission layers EML. The second common intermediate layer COM2 can be commonly disposed between the first to fourth emission layers EML and the common electrode CE.

The display panel 110 according to embodiments of the present disclosure can have a bottom emission structure, and accordingly, the common electrode CE can be a reflective electrode. That is, the common electrode CE can include a reflective electrode material.

The second light emitting device ED12 and the fourth light emitting device ED14 can be located closer to the substrate 111 than the first light emitting device ED11, the third light emitting device ED13, and the fifth light emitting device ED22.

The first light emitting device ED11, the third light emitting device ED13, and the fifth light emitting device ED22 can be located at a first height L1 from the substrate 111. The second light emitting device ED12 and the fourth light emitting device ED14 can be located at a second height L2 lower than the first height L1 from the substrate 111.

The second pixel electrode PE12 and the fourth pixel electrode PE14 can be located closer to the substrate 111 than the first pixel electrode PE11, the third pixel electrode PE13, and the fifth pixel electrode PE22.

Referring to FIGS. 8, 9, and 10, the common electrode CE can have a plurality of inclined surfaces SLP.

The common electrode CE can have an inclined surface SLP on each side of the first upper insulating layer 920A, the second upper insulating layer 920B, and the third upper insulating layer 920C. As an example, the common electrode CE can also have an inclined surface SLP on the side of the lower insulating layer 910.

The common electrode CE can have the inclined surfaces (SLP1a/SLP1b/SLP1c/SLP1d, SLP3a/SLP3b/SLP3c/SLP3d, SLP5a/SLP5b/SLP5c/SLP5d) SLP on each of the four sides of each of the first upper insulating layer 920A, the second upper insulating layer 920B, and the third upper insulating layer 920C.

The common electrode CE can have inclined surfaces (SLP2a/SLP2b, SLP4a/SLP4b) on each of two of the four sides of the lower insulating layer 910. As an example, similar as shown in FIGS. 6 and 7, a hole may be formed between two subpixels adjacent in the second direction (e.g., the second subpixel SP12 and the fifth subpixel SP22) in the lower insulating layer 910. Accordingly, as an example, the intermediate layer EL and the common electrode CE may be disposed inside the hole along the sides of the hole of the lower insulating layer 910. Accordingly, as an example, a portion of the common electrode CE disposed inside the hole of the lower insulating layer 910 may be located closer to the substrate 111 than the pixel electrodes PE12 and PE22, without being limited thereto. As an example, a portion of the common electrode CE disposed inside the hole of the lower insulating layer 910 may be located closer to the substrate 111 than the pixel electrode PE22, but may be located farther to the substrate 111 than the pixel electrode PE12, without being limited thereto. As an example, the inclined surface SLP2b may be located on a side of the hole of the lower insulating layer 910. As an example, the inclined surface SL5a may include a first portion on a side of the third upper insulating layer 920C and a second portion on a side of the lower insulating layer 910. As an example, the hole of the lower insulating layer 910 may have a depth smaller than, equal to or greater than a height of the third upper insulating layer 920C. As an example, the first portion of the inclined surface SL5a may be longer than, equal to or shorter than the second portion of the inclined surface SL5a. As an example, the second portion of the inclined surface SL5a may have the same length as the inclined surface SLP2b, without being limited thereto. As an example, the inclined surface SL5a may further comprises a flat portion connecting the first portion and the second portion. As an example, the flat portion may be located on a portion of the lower insulating layer 910 between the hole and the third upper insulating layer 920C. As an example, the hole of the lower insulating layer 910 may expose or may not expose the first protective layer 610. As an example, a hole may be additionally or alternatively formed between two subpixels adjacent in the first direction in the lower insulating layer 910, so that the inclined surface SLP1d and SLP1c may be further disposed on a side of the hole in the lower insulating layer 910. As an example, the inclined surface in the first direction (e.g., the inclined surface SLP1d and SLP1c, SLP3c and SLP3d, SLP5c and SLP5d) may have the same or substantially the same structure, without being limited thereto. As an example, the inclined surface in the second direction may have the same or substantially the same structure as the inclined surface SLP5a or the inclined surface SLP2a, without being limited thereto. As an example, the inclined surface SLP1a and SLP1b may have the same or substantially the same structure as the inclined surface SLP5a, without being limited thereto.

As described above, the first light emitting device ED11 of the first subpixel SP11 can be formed of the first pixel electrode PE11, the intermediate layer EL, and the common electrode CE, the second light emitting device ED12 of the second subpixel SP12 can be formed of the second pixel electrode PE12, the intermediate layer EL, and the common electrode CE, the third light emitting device ED13 of the third subpixel SP13 can be formed of the third pixel electrode PE13, the intermediate layer EL, and the common electrode CE, the fourth light emitting device ED14 of the fourth subpixel SP14 can be formed of the fourth pixel electrode PE14, the intermediate layer EL, and the common electrode CE, and the fifth light emitting device ED22 of the fifth subpixel SP22 can be formed of the fifth pixel electrode PE22, the intermediate layer EL, and the common electrode CE.

The common electrode CE can have four first inclined surfaces SLP1a, SLP1b, SLP1c and SLP1d located on the four sides of the first light emitting device ED11, two second inclined surfaces SLP2a and SLP2b located on two of the four sides of the second light emitting device ED12, four third inclined surfaces SLP3a, SLP3b, SLP3c and SLP3d) located on the four sides of the third light emitting device ED13, two fourth inclined surfaces SLP4a and SLP4b located on two of the four sides of the fourth light emitting device ED14, and four fifth inclined surfaces SLP5a, SLP5b, SLP5c and SLP5d located on the four sides of the fifth light emitting device ED22.

The number of second inclined surfaces SLP2a and SLP2b of the common electrode CE around the second light emitting device ED12 of the second subpixel SP12 and the number of fourth inclined surfaces SLP4a and SLP4b of the common electrode CE around the fourth light emitting device ED14 of the fourth subpixel SP14 can each be smaller than each of the number of first inclined surfaces SLP1a, SLP1b, SLP1c and SLP1d of the common electrode CE around the first light emitting device ED11 of the first subpixel SP11, the number of third inclined surfaces SLP3a, SLP3b, SLP3c and SLP3d of the common electrode CE around the third light emitting device ED13 of the third subpixel SP13, and the number of fifth inclined surfaces SLP5a, SLP5b, SLP5c and SLP5d of the common electrode CE around the fifth light emitting device ED22 of the fifth subpixel SP22.

The first light emitted from the first light emitting device ED11 can be reflected from the four first inclined surfaces SLP1a, SLP1b, SLP1c and SLP1d, and can travel toward the substrate 111 to be emitted out of the display panel 110.

The second light emitted from the second light emitting device ED12 can be reflected from the two second inclined surfaces SLP2a and SLP2b, and can travel toward the substrate 111 to be emitted out of the display panel 110.

The third light emitted from the third light emitting device ED13 can be reflected from the four third inclined surfaces SLP3a, SLP3b, SLP3c and SLP3d, and can travel toward the substrate 111 to be emitted out of the display panel 110.

The fourth light emitted from the fourth light emitting device ED14 can be reflected from the two fourth inclined surfaces SLP4a and SLP4b, and can travel toward the substrate 111 to be emitted out of the display panel 110.

The fifth light emitted from the fifth light emitting device ED22 can be reflected from the four fifth inclined surfaces SLP5a, SLP5b, SLP5c and SLP5d, and can travel toward the substrate 111 to be emitted out of the display panel 110.

Meanwhile, FIGS. 11 and 12 can correspond to FIGS. 9 and 10, respectively.

Referring to FIGS. 9 and 10, the first upper insulating layer 920A, the second upper insulating layer 920B, and the third upper insulating layer 920C can be insulating layers different from the lower insulating layer 910. As an example, at least one or each of the first upper insulating layer 920A, the second upper insulating layer 920B, and the third upper insulating layer 920C may be formed separately with the lower insulating layer 910. As an example, at least one or each of the first upper insulating layer 920A, the second upper insulating layer 920B, and the third upper insulating layer 920C may be formed of a material different from or the same as that of the lower insulating layer 910.

Alternatively, the first upper insulating layer 920A, the second upper insulating layer 920B, and the third upper insulating layer 920C can be formed integrally with the lower insulating layer 910.

In FIGS. 11 and 12, the insulating layer 1100 can be an insulating layer in which a first upper insulating layer 920A, a second upper insulating layer 920B, a third upper insulating layer 920C, and a lower insulating layer 910 are formed integrally.

Referring to FIGS. 11 and 12, an insulating layer 1100 having a step portion can be formed through a half-tone mask process. That is, the insulating layer 1100 including the first upper insulating layer 920A, the second upper insulating layer 920B, and the third upper insulating layer 920C can be formed through a half-tone mask process. As an example, a step portion of a greater height of the insulating layer 1100 may correspond to the first upper insulating layer 920A, the second upper insulating layer 920B, and the third upper insulating layer 920C, while a step portion of a smaller height of the insulating layer 1100 may correspond to the lower insulating layer 910.

As described above, according to the light extraction structure for high-resolution according to the embodiments of the present disclosure, a mirror MR is formed around the subpixel, thereby increasing the light extraction efficiency of the corresponding subpixel.

According to the light extraction structure for high-resolution according to the embodiments of the present disclosure, in the case of a specific subpixel (e.g., SP12), a mirror MR can be formed only in a portion of the surrounding area. For example, in the case of the second subpixel SP12, mirrors MR can be formed on only two of the four sides surrounding the second subpixel, and mirrors MR can be not formed on the remaining two sides. Accordingly, it is possible to reduce the space for forming the light extraction structure, which can help implement the high-resolution display panel 110.

Depending on the light extraction structure for high-resolution according to embodiments of the present disclosure, there can be different the number of mirrors MRs existing around each subpixel. Accordingly, there can be a difference in light extraction efficiency between subpixels with different numbers of mirrors n(MR). Deviation in light extraction efficiency between subpixels can cause luminance deviation, resulting in image spotting.

Accordingly, the display device 100 according to embodiments of the present disclosure can perform data compensation processing to reduce or eliminate luminance deviation due to deviation in light extraction efficiency between subpixels.

In the display device 100 according to embodiments of the present disclosure, a first data voltage for emitting light of a first luminance can be supplied to the first subpixel SP11, a second data voltage for emitting light of a second luminance can be supplied to the second subpixel SP12, a third data voltage for emitting light of a third luminance can be supplied to the third subpixel SP13, a fourth data voltage for emitting light of a fourth luminance can be supplied to the fourth subpixel SP1, and a fifth data voltage for emitting light of a fifth luminance can be supplied to the fifth subpixel SP22.

According to the data compensation processing of the display device 100 according to embodiments of the present disclosure, when the first to fifth luminances are the same, the second data voltage and the fourth data voltage can be higher than the first data voltage, the third data voltage, and the fifth data voltage.

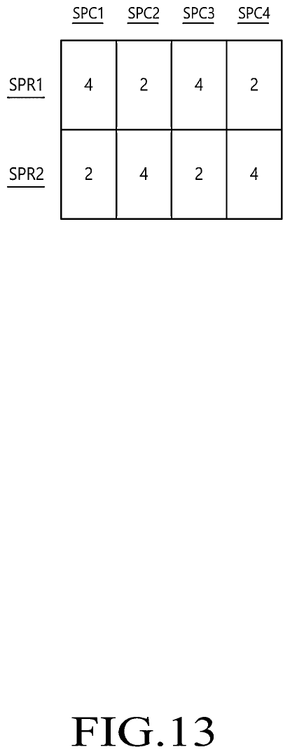

Hereinafter, a light extraction structure for high-resolution according to embodiments of the present disclosure will be exemplarily described with reference to FIGS. 13 to 15. However, FIGS. 8 to 12 are also referred in the following description. In the following description, the first subpixel row SRR1 and the second subpixel row SPR2 can be referred to as a first row and a second row, respectively, and the first subpixel column SPC1 and the second subpixel column SPC2, the third subpixel column SPC3, and the fourth subpixel column SPC4 can be referred to as a first column, a second column, a third column, and a fourth column, respectively.

FIG. 13 illustrates the number of mirrors n(MR) per subpixel of the display panel 110 according to embodiments of the present disclosure.

Referring to FIG. 13, in the four subpixels SP11, SP12, SP13 and SP14 arranged in the first subpixel row SPR1, the number of mirrors n(MR) of the subpixels SP11 and SP13 arranged in the odd subpixel column SPC1 and SPC3 and the number of mirrors n(MR) of the subpixels SP12 and SP14 arranged in the even subpixel columns SPC2 and SPC4 can be different from each other.

For example, in the four subpixels SP11, SP12, SP13 and SP14 arranged in the first subpixel row SPR1, the number of mirrors n(MR) of the subpixels SP11 and SP13 arranged in the odd subpixel column SPC1 and SPC3 can be 4, and the number of mirrors n(MR) of the subpixels SP12 and SP14 arranged in the even subpixel columns SPC2 and SPC4 can be 2.

In the four subpixels SP21, SP22, SP23 and SP24 arranged in the second subpixel row SPR2, the number of mirrors n(MR) of the subpixels SP21 and SP23 arranged in the odd subpixel column SPC1 and SPC3, and the number of mirrors n(MR) of the subpixels SP22 and SP24 arranged in the even subpixel columns SPC2 and SPC4 can be different from each other.

For example, in the four subpixels SP21, SP22, SP23 and SP24 arranged in the second subpixel row SPR2, the number of mirrors n(MR) of the subpixels SP21 and SP23 arranged in the odd subpixel column SPC1 and SPC3 can be 2, and the number of mirrors n(MR) of the subpixels SP22 and SP24 arranged in the even subpixel columns SPC2 and SPC4 can be 4.

According to the above, the number of mirrors n(MR) of each of the four subpixels SP11, SP12, SP13 and SP14 arranged in the first subpixel row SPR1 can be, in order, 4, 2, 4, and 2. The number of mirrors n(MR) of each of the four subpixels SP21, SP22, SP23 and SP24 arranged in the second subpixel row SPR2 can be 2, 4, 2, and 4, in that order.

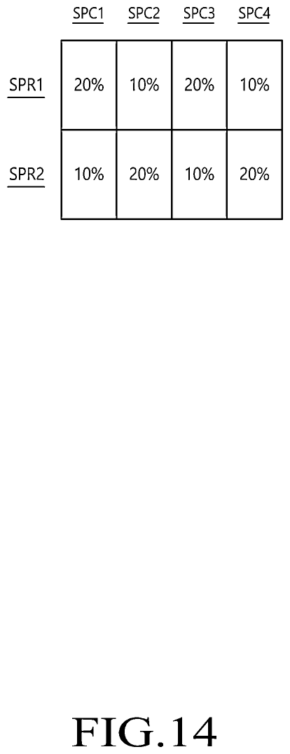

FIG. 14 illustrates light extraction efficiency for each subpixel of a display panel 110 according to embodiments of the present disclosure.

Referring to FIG. 14, in the four subpixels SP11, SP12, SP13 and SP14 arranged in the first subpixel row SPR1, the subpixels SP11 and SP13 arranged in the odd subpixel column SPC1 and SPC3, and the subpixels SP12 and SP14 arranged in the even subpixel columns SPC2 and SPC4 can have different light extraction efficiencies due to the difference in the number of mirrors n(MR).

In the four subpixels SP21, SP22, SP23 and SP24 arranged in the second subpixel row SPR2, the subpixels SP21 and SP23 arranged in the odd subpixel column SPC1 and SPC3, and the subpixels SP22 and SP24 arranged in the even subpixel columns SPC2 and SPC4 can have different light extraction efficiencies due to the difference in the number of mirrors n(MR).

The light extraction efficiency of subpixels SP12, SP14, SP21 and SP23 with the mirror numbers n(MR) of 2 can have a first efficiency value (e.g., 5%, 10%, 15%, etc.).

The light extraction efficiency of the subpixels SP11, SP13, SP22 and SP24 with the mirror number n(MR)) of 4 can have a second efficiency value (e.g., 15%, 20%, 25%, etc.) higher than the first efficiency value (e.g., 5%, 10%, 15%, etc.).

According to the light extraction structure for high-resolution according to the embodiments of the present disclosure, the light extraction efficiency can indicate a degree of the increase of the amount of light emitted outside the display panel 110 in a case with mirrors MR of the corresponding number of mirrors n(MR), compared to the amount of light emitted outside the display panel 110 in a case without a mirror MR.

The light extraction efficiency of each of the four subpixels SP11 to SP14 arranged in the first subpixel row SPR1 can be 20%, 10%, 20%, and 10%. The light extraction efficiency of each of the four subpixels SP21 to SP24 arranged in the second subpixel row SPR2 can be 10%, 20%, 10%, and 20%.

As described above, according to the light extraction structure for high-resolution according to the embodiments of the present disclosure, a mirror MR is formed around the subpixel, so that it is possible to increase the light extraction efficiency of the corresponding subpixel.

According to the light extraction structure for high-resolution according to the embodiments of the present disclosure, in the case of a specific subpixel (e.g., SP12), a mirror MR can be formed only in a portion of the surrounding area. For example, in the case of the second subpixel SP12, mirrors MR can be formed on only two of the four sides surrounding the second subpixel, and mirrors MR are not formed on the remaining two sides. Accordingly, the space for forming the light extraction structure can be reduced, which can help implement the high-resolution display panel 110.

Depending on the light extraction structure for high-resolution according to embodiments of the present disclosure, the number of mirrors MRs existing around each subpixel can be different. Accordingly, there can be a difference in light extraction efficiency between subpixels with different numbers of mirrors.

According to the light extraction structure for high-resolution according to the embodiments of the present disclosure, the number of mirrors MR (e.g., 2) for a specific subpixel (e.g., SP12) can be less than the number of mirrors (MR) (e.g., 4) of another subpixel (e.g., SP11).

As the number of mirrors MRs around the light emitting device of a subpixel increases, the light extraction efficiency of the subpixel can increase.

For example, in the case of the second subpixel SP12 and the fourth subpixel SP14, the number of mirrors around the corresponding light emitting devices ED12 and ED14 is 2. In the case of the first subpixel SP11, the third subpixel SP13, and the fifth subpixel SP22, the number of mirrors around the corresponding light emitting devices ED11, ED13 and ED22 is 4. For example, the light extraction efficiency of the second subpixel SP12 and the fourth subpixel SP14 can be about the first efficiency value (e.g., 10(%)). The light extraction efficiency of the fifth subpixel SP22 can be a second efficiency value (e.g., 20(%)) that is higher than the first efficiency value (e.g., 10(%)).

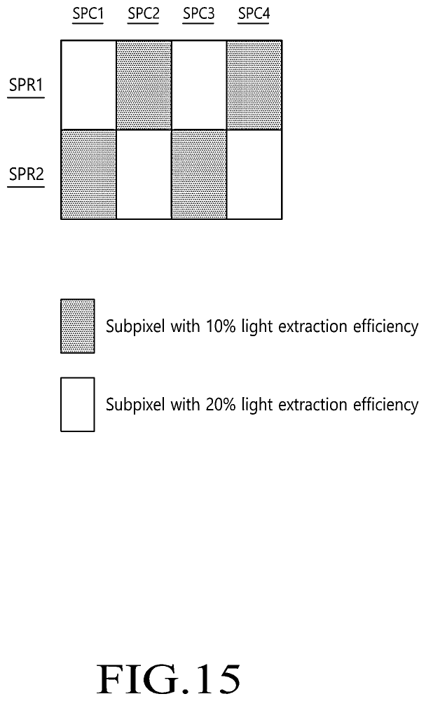

FIG. 15 illustrates the light emission state for each subpixel of the display panel 110 according to embodiments of the present disclosure.

Referring to FIGS. 14 and 15, in the case of eight subpixels SP11 to SP14 and SP21 to SP24 arranged in the first subpixel row SPR1 and the second subpixel row SPR2, since there are the mirror MR, there can have a higher light extraction efficiency than the efficiency value (e.g. 0(%)), which is the light extraction efficiency in the case where there is no mirror MR, so the luminance can increase compared to the case where there is no mirror MR.

Among the eight subpixels SP11 to SP14 and SP21 to SP24 arranged in the first subpixel row SPR1 and the second subpixel row SPR2, he number of mirrors n(MR) and light extraction efficiency of some subpixels can be different from the number of mirrors n(MR) and light extraction efficiency of other subpixels.

Even if the same data voltage VDATA is applied to eight subpixels SP11 to SP14 and SP21 to SP24 arranged in the first subpixel row SPR1 and the second subpixel row SPR2, the larger the number of mirrors n(MR) in a subpixel and the higher the light extraction efficiency, the brighter the luminance of the subpixel can be.

Even if the same data voltage VDATA is applied to eight subpixels SP11 to SP14 and SP21 to SP24 arranged in the first subpixel row SPR1 and the second subpixel row SPR2, the light emission luminance of the subpixels SP12, SP14, SP21 and SP23 having a light extraction efficiency of a first efficiency value (e.g., 10%), and the light emission luminance of subpixels SP11, SP13, S22 and SP24 having a light extraction efficiency of a second efficiency value ((e.g., 20%) higher than the first efficiency value (e.g., 10%) can be different from each other due to the differences in light extraction structure (e.g., number of mirrors, light extraction efficiency).

Even if the same data voltage VDATA is applied to eight subpixels SP11 to SP14 and SP21 to SP24 arranged in the first subpixel row SPR1 and the second subpixel row SPR2, the luminance of the subpixels SP11, SP13, S22 and SP24 with the light extraction efficiency of the second efficiency value (e.g., 20%) can be the brighter, and the light emission luminance of the subpixels SP12, SP14, SP21 and SP23 having a light extraction efficiency of a first efficiency value (e.g., 10%) can be relatively dark.

According to the light extraction structure for high-resolution according to embodiments of the present disclosure, the number of mirrors n(MR) for each subpixel can be different. Therefore, even if the same data voltage VDATA is supplied to a plurality of subpixels SP11 to SP14 and SP21 to SP24, the emission luminance of some subpixels among the plurality of subpixels SP11 to SP14 and SP21 to SP24 can be different from that of the remaining subpixels. The deviation in luminance can cause spots on the display screen.

The light extraction structure for high-resolution according to embodiments of the present disclosure can effectively increase light extraction efficiency while reducing the area where the light extraction structure is formed in the display panel 110. However, in the case of a light extraction structure for high-resolution according to embodiments of the present disclosure, there can be occurred a deviation in emission luminance between subpixels.

Accordingly, the display device 100 according to embodiments of the present disclosure can provide a compensation function capable of reducing or eliminating the difference in emission luminance between subpixels caused by a light extraction structure for high-resolution.

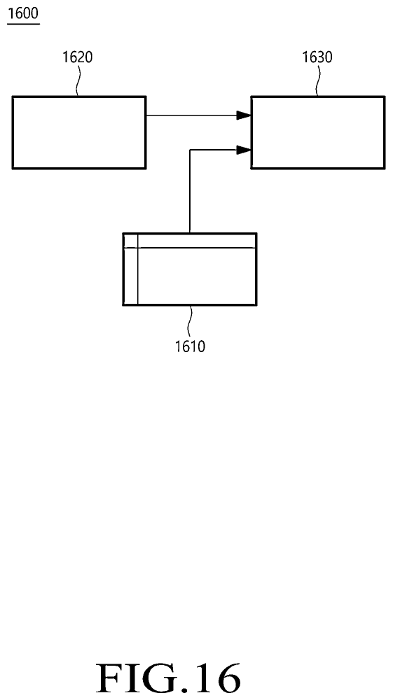

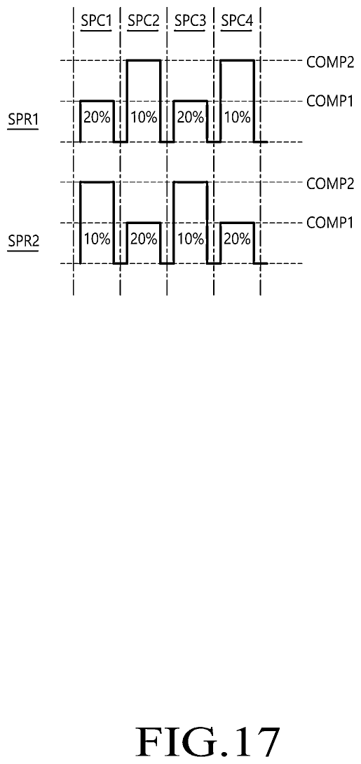

Hereinafter, it will be described a compensation function capable of reducing or eliminating the difference in emission luminance between subpixels caused by a light extraction structure for high-resolution with reference to FIGS. 16 and 17.

FIG. 16 illustrates a data compensation circuit 1600 considering the light extraction structure of a display device 100 according to embodiments of the present disclosure.

Referring to FIG. 16, the data compensation circuit 1600 considering the light extraction structure of the display device 100 according to embodiments of the present disclosure can include a lookup table 1610 including correction control information for each subpixel considering the light extraction structure, a data input unit 1620 which receives data for each subpixel, and a data correction unit 1630 which generates correction data for each subpixel by correcting the data for each subpixel based on correction control information for each subpixel.

The correction control information for each subpixel considering the light extraction structure can vary depending on the number of the inclined surfaces of the common electrode CE around the light emitting device of the corresponding subpixel.

For example, the correction control information for each subpixel can include at least one of the number of mirrors for each subpixel, light extraction efficiency for each subpixel, and a data compensation value for each subpixel. The number of mirrors for each subpixel can correspond to or be proportional to the number of inclined surfaces of the common electrode around the light emitting device of the corresponding subpixel. The light extraction efficiency for each subpixel can be proportional to the number of mirrors for each subpixel. The data compensation value for each subpixel can be inversely proportional to the number of mirrors for each subpixel or the light extraction efficiency for each subpixel.

The number of mirrors for each subpixel and the light extraction efficiency for each subpixel can correspond to or be similar to each other. For example, the number of mirrors for each subpixel and the light extraction efficiency for each subpixel can be proportional to each other. The smaller the number of mirrors for each subpixel, the lower the light extraction efficiency for each subpixel, and the greater the number of mirrors for each subpixel, the higher the light extraction efficiency for each subpixel.

The data compensation value for each subpixel can be a value corresponding to the number of mirrors for each subpixel or the light extraction efficiency value for each subpixel. For example, as the number of mirrors decreases, the data compensation value of the corresponding subpixel can increase. The larger the number of mirrors, the smaller the data compensation value of the corresponding subpixel can be. As another example, the lower the light extraction efficiency value, the larger the data compensation value of the corresponding subpixel can be. The higher the light extraction efficiency value, the smaller the data compensation value of the corresponding subpixel can be.

As an example, the data compensation circuit 1600 can be included in the controller 140. As another example, the data compensation circuit 1600 can be included in the data driving circuit 120. As another example, the data compensation circuit 1600 can be provided outside the controller 140 and the data driving circuit 120.

In the case of using the above-described data compensation circuit 1600, even if there is a difference in light extraction efficiency between subpixels due to the light extraction structure for high-resolution according to the embodiments of the present disclosure, the light emission states of subpixels with different light extraction efficiencies can all become the same or substantially the same. Accordingly, there can be reduced or prevented the image spotting due to luminance deviation.

Hereinafter, it will be described data compensation of the data compensation circuit 1600 in more detail.

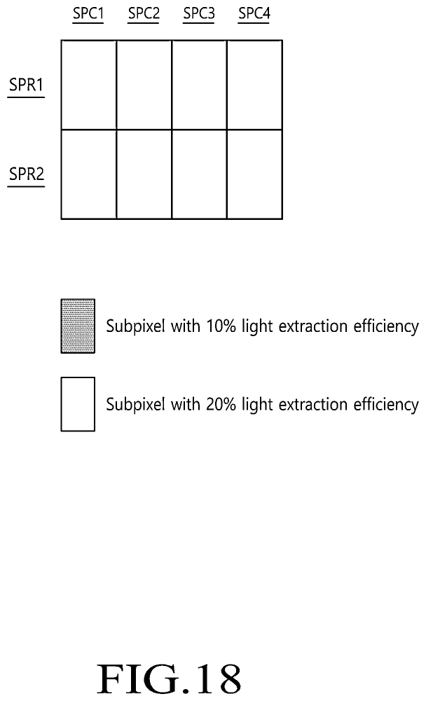

FIG. 17 illustrates data compensation values for each subpixel considering a light extraction structure of the display panel 110 according to embodiments of the present disclosure. FIG. 18 illustrates the light emission state of each subpixel after data compensation considering a light extraction structure of the display panel 110 according to embodiments of the present disclosure.

The data compensation value for each subpixel can be a value considering the light extraction structure. That is, the data compensation value for each subpixel can be a value corresponding to the light extraction efficiency value for each subpixel.

The lower the light extraction efficiency value, the larger the data compensation value of the corresponding subpixel can be. The higher the light extraction efficiency value, the smaller the data compensation value of the corresponding subpixel can be.

A low light extraction efficiency value means that the amount of light emitted to the outside of the display panel 110 is small, resulting in low luminance. Therefore, for the subpixels with low light extraction efficiency values, data compensation processing can be required to supply data capable of further increasing light emission luminance.

A high light extraction efficiency value means that the amount of light emitted to the outside of the display panel 110 is large, resulting in high luminance. Therefore, for a subpixel with a high light extraction efficiency value, data compensation processing can be required to supply data that does not increase the luminance of light or can only slightly increase the luminance, can increase the luminance of light with a lower degree as compared with that for a subpixel with a low light extraction efficiency value, or can even reduce the luminance.

As an example, the data compensation value for each subpixel may be a value varying (e.g., increasing, added to, or multiplied t, etc.) the original data.

As the data compensation value increases, the luminance of the corresponding subpixel can become brighter compared to before data compensation processing.

As the data compensation value is smaller, the luminance of the corresponding subpixel can become slightly brighter than before data compensation processing.

If the data compensation value is zero, the data supplied to the corresponding subpixel has not been compensated, so the luminance of the subpixel does not change. If the data compensation value is negative value, the luminance of the corresponding subpixel may become darker compared to before data compensation processing, without being limited thereto.

For example, referring to FIG. 17, in the case that the light extraction efficiency value is a second efficiency value (e.g., 20%), the data compensation value of the corresponding subpixels SP11, SP13, SP22 and SP24 can be a first compensation value COMP1. If the light extraction efficiency value is the first efficiency value (e.g., 10%), the data compensation value of the corresponding subpixels SP12, SP14, SP21 and SP23 can be a second compensation value COMP2. Although it is described and illustrated that there are two data compensation values including the first compensation value COMP1 and the second compensation value COMP2, embodiments are not limited thereto. As an example, the number of the data compensation values may depend on the number of mirrors MR per subpixel, as well as other factors such that the position of the corresponding subpixel, the color of the corresponding subpixel, the data supplied to the corresponding subpixel, and/or the data for the surrounding subpixels, etc., without being limited thereto.

For example, the second compensation value COMP2 can be greater than the first compensation value COMP1. As an example, the first compensation value COMP1 can be zero or even a negative value, without being limited thereto.

Since the number of mirrors is determined for each subpixel, the light extraction efficiency value for each subpixel and the data compensation value for each subpixel can be predetermined. Accordingly, at least one of the number of mirrors for each subpixel, the light extraction efficiency value for each subpixel, and the data compensation value for each subpixel can be previously stored in the lookup table 1610.

The data correction unit 1630 of the data compensation circuit 1600 considering the light extraction structure can correct the original data for each subpixel and generate correction data for each subpixel by using at least one of the number of mirrors for each subpixel, the light extraction efficiency value for each subpixel, and the data compensation value for each subpixel to subpixel.

The data driving circuit 120 can convert correction data for each subpixel into a data voltage, which is an analog voltage, and supply it to the corresponding subpixel.

The data driving circuit 120 of the display device 100 according to embodiments of the present disclosure can supply a first data voltage for emitting light of a first luminance to the subpixels SP12, SP14, SP21 and SP23 with the number of mirrors n(MR) of 2 and a light extraction efficiency of a first efficiency value (e.g., 10%), and can supply a second data voltage for emitting light of a second luminance to the subpixels SP11, SP13, SP22 and SP24 with the number of mirrors n(MR) of 4 and a light extraction efficiency of a second efficiency value (e.g., 20%).

If the first luminance and the second luminance are the same, the first data voltage can be a voltage value for correction data obtained by adding the data corresponding to the luminance and the second compensation value COMP2, and the second data voltage can be a voltage value for the correction data obtained by adding the data corresponding to the corresponding luminance and the first compensation value COMP1.

Since the second compensation value COMP2 is higher than the first compensation value COMP1, the first data voltage can be higher than the second data voltage.

Referring to FIG. 18, after data compensation considering the light extraction structure according to embodiments of the present disclosure, the emission states of subpixels with different light extraction efficiencies according to differences in the light extraction structure can all become the same or substantially the same. As an example, after data compensation considering the light extraction structure according to exemplary embodiments of the present disclosure, a difference between the emission states of subpixels with different light extraction efficiencies according to differences in the light extraction structure may be smaller than before the data compensation. Accordingly, image spotting due to luminance deviation can be prevented.

The display device 100 according to the above-described embodiments of the present disclosure will be briefly described again in terms of the inclined surface configuration of the common electrode CE as follows.

The display device 100 according to embodiments of the present disclosure can include a substrate 111, a first pixel electrode PE11, a second pixel electrode PE12, and a third pixel electrode PE13, an intermediate layer EL on the first pixel electrode PE11, the second pixel electrode PE12 and the third pixel electrode PE13, and a common electrode CE on the intermediate layer EL.

The first pixel electrode PE11 and the third pixel electrode PE13 can be located higher from the substrate 111 than the second pixel electrode PE12.

The common electrode CE can include an inclined surface SLP1d which extends from the top of the first pixel electrode PE11, passes through one side of the first pixel electrode PE11, and extends to the top of the second pixel electrode PE12, and an inclined surface SLP3c which extends from the top of the third pixel electrode PE13, passes through the other side of the third pixel electrode PE13, and extends to the top of the second pixel electrode PE12.

The display device 100 according to embodiments of the present disclosure can further include an insulating layer 920A and 920B which is not disposed under the second pixel electrode PE12, but is disposed under the first pixel electrode PE11 and the third pixel electrode PE13.

From the perspective of data compensation for reducing or eliminating the luminance deviation due to the deviation in light extraction efficiency for each subpixel of the display device 100 according to the above-described embodiments of the present disclosure, it will be briefly described again as follows.

The display device 100 according to embodiments of the present disclosure can include a substrate 111, a first subpixel SP11 including the first light emitting device ED11, a second subpixel SP12 adjacent to the first subpixel SP11 in a first direction and including a second light emitting device ED12, a first data line DL supplying a first data voltage to the first subpixel SP11, and a second data line DL supplying a second data voltage to the second subpixel SP12.

The first light emitting device ED11 can be located at a first height L1 from the substrate 111. The second light emitting device ED12 can be located at a second height L2 lower than the first height L1 from the substrate 111.

In the case that the emission luminance of the first subpixel SP11, the emission luminance of the second subpixel SP12, and the emission luminance of the third subpixel SP13 are the same, the second data voltage can be higher than the first data voltage. As an example, a data compensation value for the second data voltage may be greater than a data compensation value for the first data voltage, without being limited thereto.

The display device 100 according to embodiments of the present disclosure can include a first protective layer 610 on a substrate 111, a lower insulating layer 910 on the first protective layer 610, a first upper insulating layer 920A located on the lower insulating layer 910, a first pixel electrode PE11 located on the first upper insulating layer 920A, a second pixel electrode PE12 located on the lower insulating layer 910 and disposed on one side of the first upper insulating layer 920A, an intermediate layer EL on the first pixel electrode PE11 and the second pixel electrode PE12, and a common electrode CE on the intermediate layer EL.

The first light emitting device ED11 can include a first pixel electrode PE11, an intermediate layer EL, and a common electrode CE, and the second light emitting device ED12 can include a second pixel electrode PE1, an intermediate layer EL and a common electrode CE.

The common electrode CE can have four inclined surfaces SLP1a, SLP1b, SLP1c and SLP1d located on the four sides of the first upper insulating layer 920A, and two inclined surfaces SLP2a and SLP2b located on two of the four sides of the lower insulating layer 910.

The display device 100 according to the above-described embodiments of the present disclosure will be briefly described again in terms of the inclined surface configuration (i.e., mirror configuration) of the common electrode CE as follows.

The display device 100 according to embodiments of the present disclosure can include a substrate 111, a first pixel electrode PE11, a second pixel electrode PE12, and a third pixel electrode PE13, an intermediate layer EL on the first pixel electrode PE11, the second pixel electrode PE12 and the third pixel electrode PE13, and a common electrode CE on the intermediate layer EL.

The first pixel electrode PE11 and the third pixel electrode PE13 can be located higher from the substrate 111 than the second pixel electrode PE12.

The common electrode CE can include an inclined surface SLP1d which extends from the top of the first pixel electrode PE11, passes through one side of the first pixel electrode PE11, and extends to the top of the second pixel electrode PE12, and an inclined surface SLP3c which extends from the top of the third pixel electrode PE13, passes through the other side of the third pixel electrode PE13, and extends to the top of the second pixel electrode PE12.

The display device 100 according to embodiments of the present disclosure can further include an insulating layer 920A and 920B that is not disposed under the second pixel electrode PE12, but is disposed under the first pixel electrode PE11 and the third pixel electrode PE13.

From the perspective of data compensation for reducing or eliminating the luminance deviation due to the deviation in light extraction efficiency for each subpixel of the display device 100 according to the above-described embodiments of the present disclosure, it will be briefly described again as follows.

The display device 100 according to embodiments of the present disclosure can include a substrate 111, a first subpixel SP11 including the first light emitting device ED11, a second subpixel SP12 adjacent to the first subpixel SP11 in a first direction and including a second light emitting device ED12, a first data line DL supplying a first data voltage to the first subpixel SP11, and a second data line DL supplying a second data voltage to the second subpixel SP12.

The first light emitting device ED11 can be located at a first height L1 from the substrate 111. The second light emitting device ED12 can be located at a second height L2 lower than the first height L1 from the substrate 111.

If the emission luminance of the first subpixel SP11, the emission luminance of the second subpixel SP12, and the emission luminance of the third subpixel SP13 are the same, the second data voltage can be higher than the first data voltage.

The display device 100 according to embodiments of the present disclosure can include a first protective layer 610 on a substrate 111, a lower insulating layer 910 on the first protective layer 610, a first upper insulating layer 920A located on the lower insulating layer 910, a first pixel electrode PE11 located on the first upper insulating layer 920A, a second pixel electrode PE12 located on the lower insulating layer 910 and disposed on one side of the first upper insulating layer 920A, an intermediate layer EL on the first pixel electrode PE11 and the second pixel electrode PE12, and a common electrode CE on the intermediate layer EL.

The first light emitting device ED11 can include a first pixel electrode PE11, an intermediate layer EL, and a common electrode CE, and the second light emitting device ED12 can include a second pixel electrode PE12, an intermediate layer EL and a common electrode CE.

The common electrode CE can include four inclined surfaces SLP1a, SLP1b, SLP1c and SLP1d located on the four sides of the first upper insulating layer 920A, and two inclined surfaces SLP2a and SLP2b located on two of the four sides of the lower insulating layer 910.

Embodiments of the present disclosure described above can be briefly described as follows.

A display device according to embodiments of the present disclosure can include a substrate, a first protective layer on the substrate, a lower insulating layer on the first protective layer, a first upper insulating layer located on the lower insulating layer, a second upper insulating layer located on the lower insulating layer and spaced apart from the first upper insulating layer in a first direction, a first pixel electrode on the first upper insulating layer, a second pixel electrode located on the lower insulating layer and disposed between one side of the first upper insulating layer and the other side of the second upper insulating layer, and a third pixel electrode on the second upper insulating layer.

A display device according to embodiments of the present disclosure can further include a fourth pixel electrode located on the lower insulating layer and disposed on one side of the second upper insulating layer, a third upper insulating layer located on the lower insulating layer and disposed on one side of the second pixel electrode in a second direction different from the first direction, and a fifth pixel electrode located on the third upper insulating layer. The first pixel electrode, the second pixel electrode, the third pixel electrode, the fourth pixel electrode, and the fifth pixel electrode can be include in a first subpixel, a second subpixel, a third subpixel, fourth subpixel, and a fifth subpixel, respectively.

In the display device according to embodiments of the present disclosure, the first subpixel, the second subpixel, the third subpixel, and the fourth subpixel can be arranged in a first subpixel row, and the fifth subpixel can be arranged in a second subpixel row adjacent to the first subpixel row in the second direction. The second subpixel and the fifth subpixel can be arranged in a second subpixel column.

In the display device according to embodiments of the present disclosure, the first upper insulating layer and the second upper insulating layer can be disposed in the first subpixel row, and the third upper insulating layer can be disposed in the second subpixel row.

In the display device according to embodiments of the present disclosure, the first upper insulating layer, the second upper insulating layer, and the third upper insulating layer can be disposed to be spaced apart from each other in an island shape.

In the display device according to embodiments of the present disclosure, each of the first upper insulating layer, the second upper insulating layer, and the third upper insulating layer can have a size corresponding to an emission area of the subpixel.

In the display device according to embodiments of the present disclosure, the second pixel electrode and the fourth pixel electrode can be located closer to the substrate than the first pixel electrode, the third pixel electrode, and the fifth pixel electrode.

The display device according to embodiments of the present disclosure can further include an intermediate layer located on the first pixel electrode, the second pixel electrode, the third pixel electrode, the fourth pixel electrode, and the fifth pixel electrode, and a common electrode located on the intermediate layer and including a reflective electrode material.

In the display device according to embodiments of the present disclosure, the common electrode can include a plurality of inclined surfaces.

In the display device according to embodiments of the present disclosure, the common electrode can have an inclined surface on each side of the first upper insulating layer, the second upper insulating layer, and the third upper insulating layer, and can have an inclined surface on a side of the lower insulating layer.

In the display device according to embodiments of the present disclosure, the common electrode can have an inclined surface on each of four sides of each of the first upper insulating layer, the second upper insulating layer, and the third upper insulating layer, and can have an inclined surface on each of two sides among four sides of the lower insulating layer.

In the display device according to embodiments of the present disclosure, a first light emitting device of the first subpixel can be formed by the first pixel electrode, the intermediate layer, and the common electrode, a second light emitting device of the second subpixel can be formed by the second pixel electrode, the intermediate layer, and the common electrode, a third light emitting device of the third subpixel can be formed by the third pixel electrode, the intermediate layer, and the common electrode, a fourth light emitting device of the fourth subpixel can be formed by the fourth pixel electrode, the intermediate layer, and the common electrode, and a fifth light emitting device of the fifth subpixel can be formed by the fifth pixel electrode, the intermediate layer, and the common electrode.

In the display device according to embodiments of the present disclosure, the common electrode can include four first inclined surfaces located on four sides of the first light emitting device, two second inclined surfaces located on two of the four sides of the second light emitting device, four third inclined surfaces located on four sides of the third light emitting device, two fourth inclined surfaces located on two of the four sides of the fourth light emitting device, and four fifth inclined surfaces located on four sides of the fifth light emitting device.

In the display device according to embodiments of the present disclosure, a first light emitted from the first light emitting device can be reflected from the four first inclined surfaces and travel toward the substrate, a second light emitted from the second light emitting device can be reflected from the two second inclined surfaces and travel toward the substrate, a third light emitted from the third light emitting device can be reflected from the four third inclined surfaces and travel toward the substrate, a fourth light emitted from the fourth light emitting device can be reflected from the two fourth inclined surfaces and travel toward the substrate, and a fifth light emitted from the fifth light emitting device can be reflected from the four fifth inclined surfaces and travel toward the substrate.

In the display device according to embodiments of the present disclosure, a first data voltage for emitting light of first luminance can be supplied to the first subpixel, a second data voltage for emitting light of second luminance can be supplied to the second subpixel, a third data voltage for emitting light of a third luminance can be supplied to the third subpixel, a fourth data voltage for emitting light of fourth luminance can be supplied to the fourth subpixel, and a fifth data voltage for emitting light of a fifth luminance can be supplied to the fifth subpixel. If the first to fifth luminances are the same, the second data voltage and the fourth data voltage can be higher than the first data voltage, the third data voltage, and the fifth data voltage.

The display device according to embodiments of the present disclosure can further include a data correction circuit configured to generate correction data for each subpixel by correcting data for each subpixel based on correction control information for each subpixel which varies depending on the number of inclined surfaces of the common electrode around the light emitting device of the corresponding subpixel.

In the display device according to embodiments of the present disclosure, the correction control information for each subpixel can include at least one of the number of mirrors for each subpixel, light extraction efficiency for each subpixel, and a data compensation value for each subpixel.

In the display device according to embodiments of the present disclosure, the number of mirrors for each subpixel can correspond to or can be proportional to the number of inclined surfaces of the common electrode around the light emitting device of the corresponding subpixel, the light extraction efficiency for each subpixel can be proportional to the number of mirrors for each subpixel, and the data compensation value for each subpixel can be inversely proportional to the number of mirrors for each subpixel or the light extraction efficiency for each subpixel.

In the display device according to embodiments of the present disclosure, the first upper insulating layer, the second upper insulating layer, and the third upper insulating layer can be insulating layers different from the lower insulating layer.

In the display device according to embodiments of the present disclosure, the first upper insulating layer, the second upper insulating layer, and the third upper insulating layer can be formed integrally with the lower insulating layer.

A display device according to embodiments of the present disclosure can include a substrate, a first pixel electrode, a second pixel electrode, and a third pixel electrode on the substrate, an intermediate layer on the first pixel electrode, the second pixel electrode, and the third pixel electrode, and a common electrode on the intermediate layer. The first pixel electrode and the third pixel electrode can be located higher from the substrate than the second pixel electrode.

In the display device according to embodiments of the present disclosure, the common electrode can include an inclined surface extending from an upper portion of the first pixel electrode, passing through one side of the first pixel electrode, and extending to an upper portion of the second pixel electrode, and an inclined surface extending from an upper portion of the third pixel electrode, passing through the other side of the third pixel electrode, and extending to an upper portion of the second pixel electrode.

The display device according to embodiments of the present disclosure can further include an insulating layer which is not disposed below the second pixel electrode, but is disposed in an island shape below each of the first pixel electrode and the third pixel electrode.

A display device according to embodiments of the present disclosure can include a substrate, a first subpixel including a first light emitting device, a second subpixel adjacent to the first subpixel in a first direction and including a second light emitting device, a first data line supplying a first data voltage to the first subpixel, and a second data line supplying a second data voltage to the second subpixel.

In the display device according to embodiments of the present disclosure, the first light emitting device can be located at a first height from the substrate, and the second light emitting device can be located at a second height lower than the first height from the substrate.

In the display device according to embodiments of the present disclosure, if an emission luminance of the first subpixel, an emission luminance of the second subpixel, and an emission luminance of the third subpixel are the same, the second data voltage can be higher than the first data voltage.

The display device according to embodiments of the present disclosure can further include a first protective layer on the substrate, a lower insulating layer on the first protective layer, a first upper insulating layer located on the lower insulating layer, a first pixel electrode located on the first upper insulating layer, a second pixel electrode located on the lower insulating layer and disposed on one side of the first upper insulating layer, an intermediate layer on the first pixel electrode and the second pixel electrode, and a common electrode on the intermediate layer.

In the display device according to embodiments of the present disclosure, the first light emitting device can include the first pixel electrode, the intermediate layer, and the common electrode, and the second light emitting device can include the second pixel electrode, the intermediate layer, and the common electrode.

In the display device according to embodiments of the present disclosure, the common electrode can include four inclined surfaces located on four sides of the first upper insulating layer, and two inclined surfaces located on two of the four sides of the lower insulating layer.

According to the embodiments of the present disclosure described above, it is possible to provide a display device having a light extraction structure which allows a greater amount of light among the light generated by the light emitting devices in the display panel to be emitted toward a viewing surface.

According to the embodiments of the present disclosure, it is possible to provide a display device having a light extraction structure suitable for a high-resolution display panel.

According to the embodiments of the present disclosure, it is possible to provide a display device with a compensation function capable of reducing luminance deviation for each subpixel according to a light extraction structure suitable for high-resolution display panels.

According to embodiments of the present disclosure, it is possible to increase the light extraction efficiency for light generated from light emitting devices in the display panel. Accordingly, it is possible to reduce the power consumption of the display device by increasing light extraction efficiency.

The above description and the accompanying drawings provide an example of the technical idea of the present disclosure for illustrative purposes only. Various modifications, additions and substitutions to the described embodiments will be readily apparent to those skilled in the art without departing from the spirit and scope of the present disclosure. In addition, the disclosed embodiments are intended to illustrate the scope of the technical idea of the present disclosure. Thus, the scope of the present disclosure is not limited to the embodiments shown.

What is claimed is:

1. A display device comprising:
a substrate;
a lower insulating layer on the substrate;
a first upper insulating layer on the lower insulating layer;
a first pixel electrode on the first upper insulating layer; and
a second pixel electrode on the lower insulating layer and disposed on one side of the first upper insulating layer in a first direction.

2. The display device of claim 1, further comprising:
a second upper insulating layer located on the lower insulating layer and spaced apart from the first upper insulating layer in the first direction, with the second pixel electrode interposed therebetween; and
a third pixel electrode on the second upper insulating layer.

3. The display device of claim 2, further comprising:
a fourth pixel electrode on the lower insulating layer and disposed on one side of the second upper insulating layer in the first direction;
a third upper insulating layer on the lower insulating layer and disposed on one side of the second pixel electrode in a second direction different from the first direction; and
a fifth pixel electrode on the third upper insulating layer,
wherein the first pixel electrode, the second pixel electrode, the third pixel electrode, the fourth pixel electrode, and the fifth pixel electrode are included in a first subpixel, a second subpixel, a third subpixel, a fourth subpixel, and a fifth subpixel, respectively.

4. The display device of claim 3, wherein the first subpixel, the second subpixel, the third subpixel, and the fourth subpixel are arranged in a first subpixel row, and the fifth subpixel is arranged in a second subpixel row adjacent to the first subpixel row in the second direction,
wherein the second subpixel and the fifth subpixel are arranged in a second subpixel column,
wherein the first upper insulating layer and the second upper insulating layer are disposed in the first subpixel row,
wherein the third upper insulating layer is disposed in the second subpixel row, and
wherein the first upper insulating layer, the second upper insulating layer, and the third upper insulating layer are disposed to be spaced apart from each other in an island shape.

5. The display device of claim 3, wherein each of the first upper insulating layer, the second upper insulating layer, and the third upper insulating layer has a size corresponding to an emission area of the subpixel.

6. The display device of claim 3, wherein the second pixel electrode and the fourth pixel electrode are located closer to the substrate than the first pixel electrode, the third pixel electrode, and the fifth pixel electrode.

7. The display device of claim 3, further comprising:
an intermediate layer on the first pixel electrode, the second pixel electrode, the third pixel electrode, the fourth pixel electrode, and the fifth pixel electrode; and
a common electrode on the intermediate layer and including a reflective electrode material,
wherein the common electrode includes a plurality of inclined surfaces.

8. The display device of claim 7, wherein the common electrode has an inclined surface on each side of the first upper insulating layer, the second upper insulating layer, and the third upper insulating layer, and has an inclined surface on a side of the second subpixel and the fourth subpixel.

9. The display device of claim 8, wherein the common electrode has an inclined surface on each of four sides of each of the first upper insulating layer, the second upper insulating layer, and the third upper insulating layer, and has an inclined surface on each of two sides among four sides of each of the second subpixel and the fourth subpixel.

10. The display device of claim 7, wherein the common electrode has an inclined surface on each of two sides among four sides of each of the second subpixel and the fourth subpixel in the second direction.

11. The display device of claim 7, wherein a first light emitting device of the first subpixel includes the first pixel electrode, the intermediate layer, and the common electrode,
wherein a second light emitting device of the second subpixel includes the second pixel electrode, the intermediate layer, and the common electrode,
wherein a third light emitting device of the third subpixel includes the third pixel electrode, the intermediate layer, and the common electrode,
wherein a fourth light emitting device of the fourth subpixel includes the fourth pixel electrode, the intermediate layer, and the common electrode,
wherein a fifth light emitting device of the fifth subpixel includes the fifth pixel electrode, the intermediate layer, and the common electrode, and
wherein the common electrode includes:
four first inclined surfaces located on four sides of the first light emitting device;
two second inclined surfaces located on two of the four sides of the second light emitting device;
four third inclined surfaces located on four sides of the third light emitting device;
two fourth inclined surfaces located on two of the four sides of the fourth light emitting device; and
four fifth inclined surfaces located on four sides of the fifth light emitting device.

12. The display device of claim 11, wherein a first light emitted from the first light emitting device is reflected from the four first inclined surfaces and travels toward the substrate,
wherein a second light emitted from the second light emitting device is reflected from the two second inclined surfaces and travels toward the substrate,
wherein a third light emitted from the third light emitting device is reflected from the four third inclined surfaces and travels toward the substrate,
wherein a fourth light emitted from the fourth light emitting device is reflected from the two fourth inclined surfaces and travels toward the substrate, and
wherein a fifth light emitted from the fifth light emitting device is reflected from the four fifth inclined surfaces and travels toward the substrate.

13. The display device of claim 7, wherein a first data voltage for emitting light of a first luminance is supplied to the first subpixel,
wherein a second data voltage for emitting light of a second luminance is supplied to the second subpixel,
wherein a third data voltage for emitting light of a third luminance is supplied to the third subpixel,
wherein a fourth data voltage for emitting light of fourth luminance is supplied to the fourth subpixel,
wherein a fifth data voltage for emitting light of a fifth luminance is supplied to the fifth subpixel, and
wherein, if the first to fifth luminances are the same, the second data voltage and the fourth data voltage are higher than the first data voltage, the third data voltage, and the fifth data voltage.

14. The display device of claim 13, further comprising:
a data correction circuit configured to generate correction data for each subpixel by correcting data for each subpixel based on correction control information for each subpixel which varies depending on a number of inclined surfaces of the common electrode around the light emitting device of the corresponding subpixel.

15. The display device of claim 13, wherein the correction control information for each subpixel includes at least one of a number of mirrors for each subpixel, light extraction efficiency for each subpixel, and a data compensation value for each subpixel,
wherein the number of mirrors for each subpixel corresponds to or is proportional to the number of inclined surfaces of the common electrode around the light emitting device of the corresponding subpixel,
wherein the light extraction efficiency for each subpixel is proportional to the number of mirrors for each subpixel, and
wherein the data compensation value for each subpixel is inversely proportional to the number of mirrors for each subpixel or the light extraction efficiency for each subpixel.

16. The display device of claim 3, wherein the first upper insulating layer, the second upper insulating layer, and the third upper insulating layer are insulating layers different from the lower insulating layer, or are formed integrally with the lower insulating layer.

17. The display device of claim 16, wherein the first upper insulating layer, the second upper insulating layer, and the third upper insulating layer are formed integrally with the lower insulating layer, through a half-tone mask process.

18. The display device of claim 1, further comprising:
an intermediate layer located on the first pixel electrode and the second pixel electrode; and
a common electrode located on the intermediate layer and including a reflective electrode material,
wherein the common electrode includes an inclined surface on one side wall of the first upper insulating layer facing the second pixel electrode.

19. The display device of claim 18, wherein the common electrode includes a inclined surface on each of four side walls of the first upper insulating layer.

20. The display device of claim 18, wherein a portion of the common electrode on top of the second pixel electrode is lower than the first pixel electrode.

21. The display device of claim 18, further comprising:
a second upper insulating layer located on the lower insulating layer and disposed on one side of the second pixel electrode in a second direction different from the first direction; and
a third pixel electrode located on the second upper insulating layer,
wherein the intermediate layer and the common electrode are further located on the third pixel electrode, and
wherein the common electrode further includes a first inclined surface on one side wall of the second upper insulating layer facing the second pixel electrode.

22. The display device of claim 21, wherein the lower insulating layer comprises a hole between the second pixel electrode and the second upper insulating layer, and
wherein the intermediate layer and the common electrode are disposed inside the hole along side walls of the hole of the lower insulating layer.

23. The display device of claim 22, wherein the common electrode further comprises an inclined surface on one side wall of the hole facing the second upper insulating layer.

24. The display device of claim 23, wherein a portion of the common electrode inside the hole is lower than the second pixel electrode.

25. The display device of claim 22, wherein the common electrode further comprises a second inclined surface on one side wall of the hole facing the second pixel electrode,
wherein a light emitted from the intermediate layer on the third pixel electrode is reflected from the first inclined surface and the second inclined surface and travels toward the substrate.

26. The display device of claim 1, wherein a data compensation value for a second data voltage supplied to the second pixel electrode is greater than a data compensation value for a first data voltage supplied to the first pixel electrode.

27. A display device comprising:
a first pixel electrode, a second pixel electrode, and a third pixel electrode on a substrate;
an intermediate layer on the first pixel electrode, the second pixel electrode, and the third pixel electrode; and
a common electrode on the intermediate layer,
wherein the first pixel electrode and the third pixel electrode are located higher from the substrate than the second pixel electrode, and
wherein the common electrode comprises:
an inclined surface extending from an upper portion of the first pixel electrode, passing through one side of the first pixel electrode, and extending to an upper portion of the second pixel electrode; and
an inclined surface extending from an upper portion of the third pixel electrode, passing through another side of the third pixel electrode, and extending to the upper portion of the second pixel electrode.

28. The display device of claim 27, further comprising:
an insulating layer disposed in an island shape below each of the first pixel electrode and the third pixel electrode, wherein the insulating layer is not disposed below the second pixel electrode.

29. A display device comprising:
a first subpixel including a first light emitting device on a substrate;
a second subpixel adjacent to the first subpixel in a first direction and including a second light emitting device;
a first data line configured to supply a first data voltage to the first subpixel; and
a second data line configured to supply a second data voltage to the second subpixel,
wherein the first light emitting device is located at a first height from the substrate,
wherein the second light emitting device is located at a second height lower than the first height from the substrate, and
wherein a data compensation value for the second data voltage is greater than a data compensation value for the first data voltage.

30. The display device of claim 29, wherein, if an emission luminance of the first subpixel and an emission luminance of the second subpixel are the same, the second data voltage is higher than the first data voltage.

31. The display device of claim 29, further comprising:
a lower insulating layer on the substrate;
a first upper insulating layer on the lower insulating layer;
a first pixel electrode on the first upper insulating layer;
a second pixel electrode on the lower insulating layer and disposed on one side of the first upper insulating layer;
an intermediate layer on the first pixel electrode and the second pixel electrode; and
a common electrode on the intermediate layer,
wherein the first light emitting device includes the first pixel electrode, the intermediate layer, and the common electrode, and the second light emitting device includes the second pixel electrode, the intermediate layer, and the common electrode.

32. The display device of claim 31, wherein the common electrode includes four inclined surfaces located on four sides of the first upper insulating layer, and two inclined surfaces located on two of the four sides of the second light emitting device.
